(19) United States
(12) Patent Application Publication
(10) Pub. No.: US 2025/0092575 A1
(43) Pub. Date: Mar. 20, 2025

(54) METHOD OF MAKING FLEXIBLE TRANSDUCERS

(71) Applicant: Purdue Research Foundation, West Lafayette, IN (US)

(72) Inventors: Robert A. Nawrocki, Lafayette, IN (US); Jinsheng Fan, Minneapolis, MN (US)

(73) Assignee: Purdue Research Foundation, West Lafayette, IN (US)

(21) Appl. No.: 18/889,005

(22) Filed: Sep. 18, 2024

Related U.S. Application Data
(60) Provisional application No. 63/539,077, filed on Sep. 18, 2023.
(60) Provisional application No. 63/539,081, filed on Sep. 18, 2023.

(51) Int. Cl. D01D 5/00; D06M 11/83; D06M 101/22

(52) U.S. Cl. CPC D01D 5/0038; D06M 11/83; D06M 2101/22; D10B 2321/042

(57) ABSTRACT

A method of making a stretchable transducer is disclosed. The method includes placing a polymer solution having a concentration (C) in an injectable vessel having an electrically conductive ejection port, applying a voltage (V) between the ejection port and an electrically conductive collection plate a predetermined distance away from the ejection port, ejecting the polymer solution from the injectable vessel at a flow rate (FR), thereby generating a fibrous material having a considerable β-phase on the collection plate due to electrospinning, removing the fibrous material from the collection plate, depositing conductive electrodes on top and bottom surfaces of the removed fibrous material, thereby generating a transducer, and simultaneously optimizing formation of β-phase of the fibrous material and yield of the transducer based on unwanted electrical current leakage between deposited electrodes on the top and bottom surfaces based on C, V, and FR.

### CROSS-REFERENCE TO RELATED APPLICATIONS

The present non-provisional patent application is related to and claims the priority benefit of U.S. Provisional Patent Application Ser. 63/539,077, filed Sep. 18, 2023, and further is related to and claims the priority benefit of U.S. Provisional Patent Application Ser. 63/539,081, filed Sep. 18, 2023, the contents of each of which are hereby incorporated by reference in its entirety into the present disclosure.

### STATEMENT REGARDING GOVERNMENT FUNDING

None.

### TECHNICAL FIELD

The present disclosure generally relates to method of making transducers and in particular to a method of making flexible transducers.

### BACKGROUND

This section introduces aspects that may help facilitate a better understanding of the disclosure. Accordingly, these statements are to be read in this light and are not to be understood as admissions about what is or is not prior art.

With the advancement of modern technology, there is an ongoing shift from traditional electronic products, characterized by large size, singular functionality, and high cost, towards novel, lightweight, multifunctional, and flexible electronic devices. For example, force/pressure sensors hold the potential for broad applications in soft robotics, electronic skins, and human-machine interfaces. However, fabricating such soft electrodes with conventional manufacturing techniques, such as lithography, presents significant challenges. Among the multitude of material-processing technologies, additive manufacturing (AM) has ushered in substantial innovation in the field of electronics due to its precision and control capabilities. AM technology facilitates the creation of intricate objects and patterns layer by layer directly from computer-aided designs. This bottom-up manufacturing approach offers a flexible, efficient, and cost-effective strategy for fabricating electronic devices.

Additionally, Direct ink writing (DIW) has emerged as a promising AM technique, courtesy of the potential for high resolution and a broad range of suitable printable materials. DIW can print structures layer-by-layer by extruding materials from a moving dispenser nozzle and depositing materials on a substrate. The ink dispensing via the DIW technique can be done by various forces such as pneumatic, piston, or screw. The components of a DIW system include a dispenser, a nozzle, a three-axis platform, and a computer. The direct writing parameters, such as pressure, speed, and nozzle size, as well as the printing environments, including temperature and direct writing medium, should be appropriately adjusted to ensure the creation of stable three-dimensional (3D) structures.

In recent years, DIW has become a versatile technique in the flexible electronics industry due to its low cost, fast prototyping, and scalable printing capabilities. One of the primary advantages of DIW is the ability to rapidly iterate through a wide variety of patternable designs, thereby facilitating the fabrication of electronic devices. DIW printed components offer complex structures, higher accuracy, enhanced efficiency, and improved performance. DIW enables the direct printing of materials onto a variety of substrates. The convenience and versatility of the DIW process, in conjunction with the wide selection of printable materials-ranging from metals, ceramics, and polymers to composites-make DIW a suitable technique for applications such as printing wearable devices and on-chip integrations.

Despite the rapid development, the DIW technique still exhibits certain limitations, necessitating ongoing research into optimal substrate selection. The selection of substrates for DIW printing often includes synthetic and natural materials known for their flexibility, heat resistance, smooth surface, adjustable thickness, and low cost. Electrospinning fibers have been investigated as the substrate for printing electronics via DIW. Electrospinning enables the production of nano/microscale meshes with a high surface-area-to-volume ratio, significant permeability, and adjustable pore size and porosity of the membranes. The fibrous membranes exhibit desirable mechanical properties and high flexibility, making them ideal for wearable sensors. Still, the application of electrospinning fiber membranes as substrates for printed electronics is challenging due to the high surface roughness and porosity. Additionally, microstructures formed by the electrospinning processes are prone to shortage when combined with DIW as the ink may cause an electrical short between electrodes formed on top and bottom surfaces of the devices.

Therefore, there is an unmet need for a novel approach to generate transducers that can be made economically, and provide flexibility for various applications.

### SUMMARY

A method of making a stretchable transducer is disclosed. The method includes placing a polymer solution having a concentration (C) in an injectable vessel having an electrically conductive ejection port, applying a voltage (V) between the ejection port and an electrically conductive collection plate a predetermined distance away from the ejection port, ejecting the polymer solution from the injectable vessel at a flow rate (FR), thereby generating a fibrous material having a considerable β-phase on the collection plate due to electrospinning, removing the fibrous material from the collection plate, depositing conductive electrodes on top and bottom surfaces of the removed fibrous material, thereby generating a transducer, and simultaneously optimizing formation of β-phase of the fibrous material and yield of the transducer based on unwanted electrical current leakage between deposited electrodes on the top and bottom surfaces based on C, V, and FR.

### BRIEF DESCRIPTION OF FIGURES

FIG. 1a is a schematic of a typical transducer produced by the method of the present disclosure, wherein the transducer is shown to have been produced on substrate surfaces.

FIG. 1b is a schematic of a typical electrospinning process.

FIG. 1c is a schematic of direct ink writing (DIW) printed lines varying the spacing between printed lines.

FIG. 1d, is a schematic of a fused deposition modeling (FDM) process 3 dimensional (3D) printed thermoplastic polyurethane (TPU) substrate including the definition of infill direction.

FIG. 1e, is a schematic showing printed electrode on Polyvinylidene fluoride or polyvinylidene difluoride (PVdF) microfiber structure, where parts of the printed electrodes show electrical shortage.

FIGS. 2a, 2b, 2c, 2d, 2e, and 2f are graphs of influence of electrospinning parameters including voltage, concentration of the solution, and flow rate on the size distribution of PVdF microfibers.

FIGS. 3a, 3b, 3c, 3d, 3e, and 3f are graphs of influence of electrospinning parameters including voltage, concentration of the solution, and flow rate on the size distribution of PVdF beads.

FIGS. 4a, 4b, 4c, and 4d are SEM images of electrospinning PVdF microfibers produced by different solution concentrations: (a) 9 wt. %, (b) 12 wt. %, (c) 15 wt. %, and (d) 18 wt. %. (Scale bar: 30 μm).

FIGS. 5a, 5b, 5c, and 5d are SEM images of electrospinning PVdF microfibers produced by different voltage potentials between the needle and the collector: (a) 10 kV, (b) 15 kV, (c) 20 kV, and (d) 25 kV. (Scale bar: 30 μm).

FIGS. 6a, 6b, 6c, and 6d are SEM images of electrospinning PVdF microfibers produced by different flow rates: (a) 0.24 mL/h, (b) 0.51 mL/h, (c) 1.0 mL/h, and (d) 1.70 mL/h. (Scale bar: 30 μm).

FIGS. 7a, 7b, and 7c, are graphs of β-phase of electrospinning PVdF (in %) vs. voltage in KV, concentration in wt. %, and flow rate in ml/h, respectively.

FIGS. 8a and 8b, are graphs of printed electrode line width in mm vs. gauge size of the DIW needle (note the needle referred to is not the needle of the syringe shown in FIG. 1b, but rather a needle of the 3D printing setup for DIW printing of electrodes).

FIG. 9a, is a schematic of DIW printed silver electrodes (40 mm×40 mm) with different line distances in designed electrodes' patterns.

FIG. 9b, is a schematic of different lines' distances in electrodes' patterns corresponding to the printed electrodes in FIG. 9a.

FIGS. 10a and 10b, are calculated variations of the gap width of DIW printed lines with the decreasing of the line distances based on different size of needles, wherein FIG. 10a is related to 14-gauge, 15-gauge, 18-gauge, and 20-gauge needles, and FIG. 10b is related to 21-gauge, 22-gauge, 27-gauge, and 30-gauge needles.

FIGS. 11a and 11c are graphs of calculated variations of the mean gap width of DIW printed lines in mm with the increasing of the line distances in mm based on different size of needles, wherein FIG. 11a is related to 14-gauge, 15-gauge, 18-gauge, and 20-gauge needles, and FIG. 11c is related to 21-gauge, 22-gauge, 27-gauge, and 30-gauge needles.

FIGS. 11b and 11d are graphs of calculated variations of the overlap in % with the increasing of the line distances in mm based on different size of needles, FIG. 11b is related to 14-gauge, 15-gauge, 18-gauge, and 20-gauge needles, and FIG. 11d is related to 21-gauge, 22-gauge, 27-gauge, and 30-gauge needles.

FIG. 12, is a schematic showing relationship between DIW parameters and printing results.

FIG. 13 is a graph of printing time in minutes vs. line distance in mm for different printing speeds.

FIGS. 14a and 14b, are graphs of ink volume in mL vs. line distance in mm (see definition provided in FIG. 1c) for 14 Gauge, 15 Gauge, 18 Gauge, and 20 Gauge (FIG. 14a), and for 21 Gauge, 22 Gauge, 27 Gauge, and 30 Gauge, needles sizes, respectively.

FIGS. 15a, 15b, 15c, and 15d are graphs of resistance in Ω vs. deformation of the length (ΔL/L0) in % of the printed ink, wherein Dycotec silver electrodes printed on 3D printed TPU with different infill directions annealed at 120° C. are shown in FIG. 15a, 140° C. shown in FIG. 15b, 160° C. shown in FIG. 15c, and comparison of the performance between Dycotec silver electrodes and DuPont silver electrodes printed on 3D printed TPU with the same infill direction are shown in FIG. 15d.

FIGS. 16a, 16b, 16c, and 16d are graphs of yield of the printed electrodes vs. voltage in KV (FIG. 16a), flow rate in mL/h (FIG. 16b), concentration in Wt. % (FIG. 16c), and time in hours (FIG. 16d).

FIGS. 17a and 17b, are graphs of piezoelectric output in V vs. time in seconds is provided by applying a series of step-increased known forces from 1 N to 10 N with 1 N as the increment (FIG. 17a) and applying cyclic forces with magnitude 1 N, 0.5 Hz for about 890 seconds (about 15 minutes), as provided in FIG. 17b which also provides zoomed in portions between 60 to 80 seconds as well as 800 to 820 seconds.

FIG. 18 is a block diagram that shows blocks involved in optimizing various parameters during the electrospinning process for yield and β-phase, as well as DIW process during printing of electrodes in order to strike a balance between various DIW parameters.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel approach is presented herein to generate transducers that can be made economically, and provide flexibility for various applications. Towards this end, a method of manufacturing a flexible transducer is presented. A transducer is a device that in one more can measure changes in the environment and generate an electrical signal commensurate with those changes; however, in another mode, a transducer is capable of receiving an electrical signal and cause changes in the environment. For example, a microphone and a speaker may share the same transducer, in which in one more, changes in the environment due to movement of air because sound being received by the transducer can cause an electrical signal that can be received and amplified by a circuit. Conversely, application of an electrical signal to the same transducer may cause vibrations that can move air around the transducer, thus generating sound. In many such applications, the transducer needs to be formed on a flexible substrate to thereby allow the transducer to change shape without deleterious effects in its operation or structural integrity.

To achieve such a flexible transducer, the present disclosure describes an electrospinning process that is optimized for high sensitivity and high yield of the transducer and which is merged with a 3-dimensional (3D) printing to deposit metallic electrodes in a line-by-line manner on top and bottom surfaces of the transducer in which the lines are at worst abutting each other.

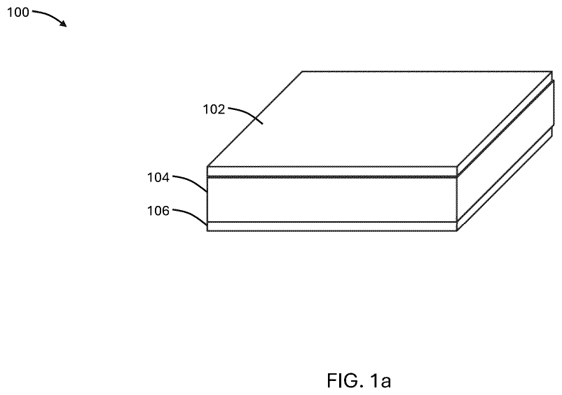

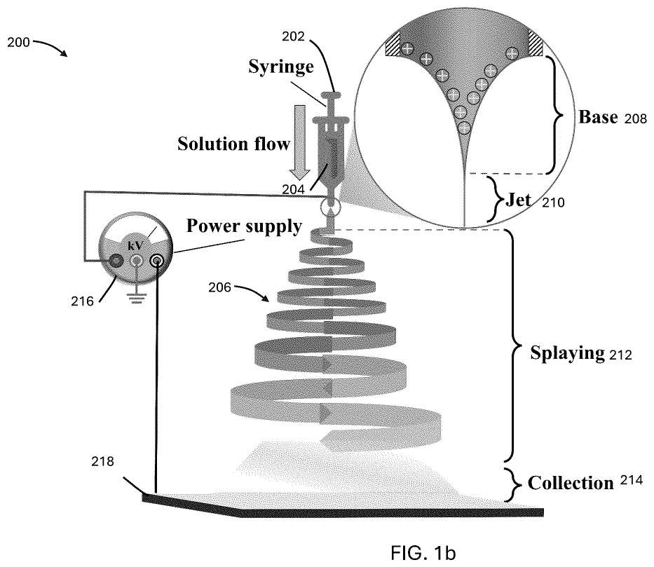

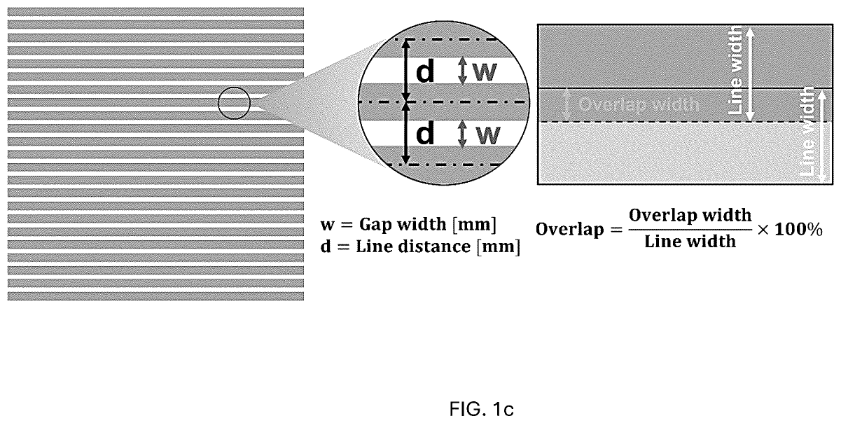

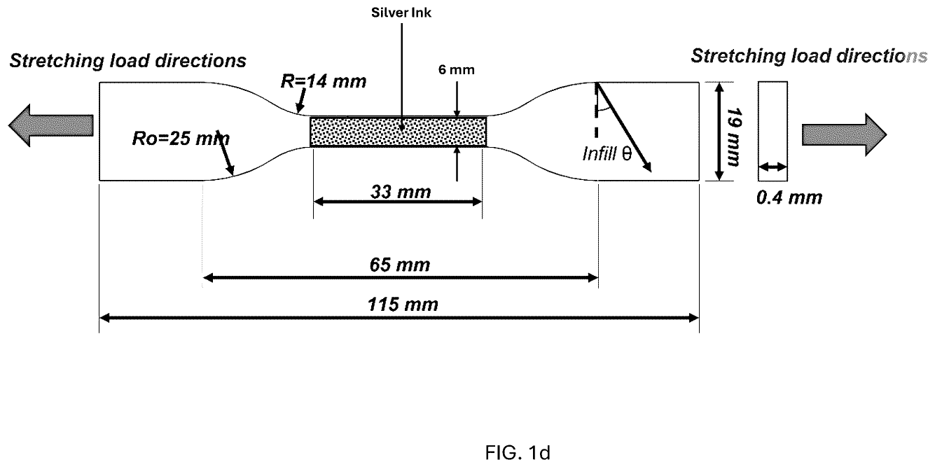

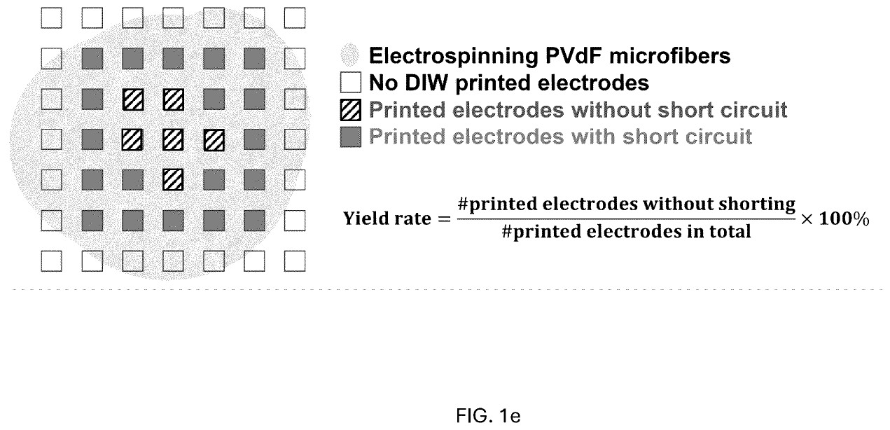

Referring to FIG. 1a, a typical transducer 100 produced by the method of the present disclosure is provided. The transducer 100 includes metallic electrodes 102 and 106, e.g., silver, which are deposited on top and bottom surfaces of a Polyvinylidene fluoride or polyvinylidene difluoride (PVdF) microstructure 104. The PVdF microstructure is generated by an electrospinning process. The structure shown in FIG. 1a may be formed on a substrate (not shown) with another protective substrate on the top surface (not shown). Additionally, a polymer encapsulation layer may also be formed on the device for protection from the environment.

The wetting properties of the electrospinning structure can be adjusted by selecting hydrophilic or hydrophobic polymers. The surface properties of electrospinning polymer fibers can be fine-tuned via electrospinning parameters or additional nanoparticles. For instance, researchers used inkjet printing to deposit silver nanoparticles (AgNPs) on polyurethane (PU) fibers to create an antimicrobial membrane for water purification.

The electrospinning technique is a relatively simple, economical, and versatile process to directly produce transducer active PVdF nano/microfibers to build transducers with features of flexibility, biocompatibility, and cost-benefit. PVdF nano/microfibers produced by electrospinning technology already have strong transducer characteristics without requiring extra mechanical stretching and electrical poling. Electrospinning PVdF nano/microfibers can have even higher electrical output under certain deformations than conventional manufactured transducer PVdF films. As shown in FIG. 1a, the typical structure of an electrospinning PVdF nano/microfiber-based force/pressure transducer has a layer of PVdF microstructure 104 sandwiched between two electrodes 102 and 106 connected with the measuring circuit (not shown), which are the core component of a transducer. The application of electrospinning PVdF nanofibers to build force/pressure transducer would not only simplify the preparation of the materials and save the need for post-processing but also improve the mechanical-to-electrical conversion efficiency of the transducer materials, which leads to high-sensitivity transducers.

Many researchers have studied the electrospinning PVdF nano/microfibers for varying applications and reported the macromolecular orientation, crystalline structures, and the effect of additives in PVdF electrospinning nano/microfibers. A study conducted in 2007 examined the polymorphism behavior, morphology, and molecular orientation of PVdF fibers produced by electrospinning. Researchers observed that the electrospinning of PVdF from a mix of N,N-dimethylformamide and acetone resulted in the creation of the β-phase. However, when these same solutions were used in spin-coating, only α- and γ-phases were identified. When PVdF fibers were electrospinning using a rotating disk collector to align them, the β-phase crystals showed a preferential alignment along the axis of the fiber. Interestingly, the orientation did not significantly fluctuate based on the rotation speed of the disk collector. The size or rotation speed of the disk collector did not enhance the β-phase, which indicated the alignment was driven by Columbic force, not the mechanical or shear forces applied by the disk collector. The Columbic force can stimulate local changes in a structure, leading to a more straightened all-trans planar zigzag conformation (TTTT) conformation and consequently increasing the β-phase content. One researcher reported that the primary reason for the increasing of the β-phase during electrospinning process is due to the mechanical and electrostatic forces exerted on the polymer solution. High voltages applied during electrospinning can stretch the polymer jet, aligning the PVdF molecular chain dipoles. The alignment effect facilitates the transition from α- to β-phase.

In 2008, a comprehensive investigation by one group of researchers revealed the impact of electrospinning on the structural characteristics of PVdF fibers. The β-phase content in PVdF fibers was controlled by manipulating the electrospinning parameters. During the experiment, maximum β-phase content fibers were achieved either by electrospinning from low-viscosity solutions or by applying a higher voltage for high-viscosity solutions. The elevated β-phase produced by using high-viscosity solutions spun at higher voltages resulted in electric poling facilitated by the amplified electric field between the syringe tip and the collector. The results proved that electrospinning offered a straightforward, single-step method to produce highly crystalline PVdF fibers predominantly in the β-phase.

Furthermore, in the same year, the same group studied the effect of nanoparticles on the microstructure of electrospinning PVdF nano/microfibers. Researchers found that introducing a well-dispersed nanoparticle phase induced the formation of PVdF phases with expanded chain structures. When nanoparticle concentrations were increased, the α-phase was entirely transformed to the more extended β- and γ-phases.

In recent years, numerous researchers have highlighted the critical role of β-phase formation and the direct impact on the piezoelectric response of electrospinning PVdF nano/microfibers. To ensure optimal performance of piezoelectric devices, high content of the β-phase in PVdF material is preferred. Different approaches were integrated into the electrospinning procedure to enhance the β-phase content. These approaches are classified into three primary categories: additions of additives into polymer solutions, adjustments to processing conditions (such as changes in thickness, the type of substrate, and diverse collection methods), and post-processing treatments (like drawing, annealing, and poling).

Towards this end, the present disclosure aims to describes a methodology for suitability of commonly used electrospinning PVdF microfiber membrane as an electrically active polymer (EAP) substrates for direct ink writing (DIW) to fabricate soft microfiber-based transducers, e.g., piezoelectric devices. The characteristics of PVdF nano/microfibers, produced by applying the electrospinning technique from N, N-dimethylformamide/acetone solvent mixtures, were studied by varying electrospinning parameters. The size distribution of electrospinning PVdF fibers was found to be in the microscale. The morphology of microfibers was assessed by scanning electron microscopy (SEM). The influence of the electrospinning parameters, including PVdF concentration in the solution, solution flow rate, applied voltage, and time, on nanofiber morphology was studied, respectively. Generally, the electrospinning parameters turn out to be capable of strongly affecting the β-phase formation. Fourier-transform infrared spectroscopy (FTIR) was used to study the β-phase content in the crystalline region of electrospinning PVdF microfibers. Besides electrospinning PVdF microfibers, the combination of DIW and electrospinning as a novel method was applied to print robust and stretchable transducers. The present disclosure is the first demonstration of using DIW to print stretchable silver ink on an electrospinning PVdF microfiber membrane to obtain desired electrode patterns. However, the porous nature of the electrospinning PVdF microfibers as the substrate for printing caused leakage of the conductive ink through the fibrous matrix, leading to electrical shorting between the printed top and bottom electrodes. To circumvent the perceived challenge, the influence of electrospinning parameters on the yield of sensors when applying DIW to print silver electrodes on both sides of the electrospinning PVdF microfiber membrane without electrical shorting was also studied. The transducer performance was quantified by applying a series of known forces at 0.5 Hz and measuring the transducer output. The transducer was measured to find that the magnitude of mechanical input and the amplitude of transducer output has a linear positive correlation similar to conventional manufactured PVdF pressure sensors. The cyclic loading-and-unloading test results show the transducer output has good reproducibility and stability. Combining DIW and electrospinning as a novel fabrication technique is a potentially effective method for fabricating high-performance soft electronics.

Electrospinning utilizes the power of electric forces to generate polymer strands with diameters at the nanoscale or microscale. Referring to FIG. 1b, a schematic of a typical electrospinning process 200 is shown. The electrospinning process 200 includes a deposition syringe 202 (or any other injectable vessel) which uses a source of force to eject a polymer solution 204 out of the syringe 202. The force results in an electrospinning jet 206. A stable electrospinning jet 206 includes four regions: a base region 208, a jet region 210, a splaying region, 212 and a collection region 214. The electrospinning process takes place when electrical forces generated from a power supply 216 surpass the surface tension at the surface of a polymer solution 204, triggering the expulsion of an electrically charged stream. Once the stream undergoes drying or solidification due to solvent evaporation, the stream leaves behind an electrically charged thread. The charged thread is controlled and sped up by electrical forces, allowing the deposition of the charged thread on collectors 218 that could take the form of sheets or other geometric shapes. The stable electrospinning jet 206 originates from the electrically charged area at the base region 208, traverses through the jet region 210, splits into numerous strands in the splaying region 212, and concludes in the collection region 214.

Much of the research regarding electrically driven jets has focused on the initial processes that turn a liquid surface into a jet. The liquid surface near the base of a single jet initially appears almost flat across the needle's open tip. When a high voltage is applied to the needle's liquid, the surface is pulled into a spherical section by the electrical forces and surface tension. As this bulge takes shape, charges move within the liquid and concentrate on the most protruding surface area. The accumulation of the charge enhances the surface's protrusion, and since the charge density is highest near the peak protrusion, the surface is drawn into a conical shape. One researcher examined the conditions at a droplet's point that is distorted by an electrical field. This researcher's analysis demonstrated that a conical interface between two fluids maintains stability when the semi-angle of the cone is 49.3°. This shape is mathematically defined by this researcher and is commonly known as the Taylor cone. The charge density at the cone's tip increases as the radius shrinks. As the applied voltage rises, a liquid jet is drawn from the cone's tip, initiating the process of electrospinning.

Referring back to FIG. 1a, the PVdF is deposited on a substrate, e.g., thermoplastic polyurethane (TPU). The TPU substrate is manufactured according to a variety of methods known to a person having ordinary skill in the art. One such method is 3D printing. An X60 Ultra Flexible Filament (diameter 1.75 mm, shore hardness of 60 A, and tensile strength 35 MPa) was dried at 40° C. for one hour prior to printing to eliminate the influence of moisture. Shore hardness is a scale, known to a person having ordinary skill in the art, which measures the elastic hardness of materials based on the elastic reaction of the material when an object is dropped on it. It is determined as a number from 0 to 100 on scales A or D. The higher the number, the greater the hardness. The stereolithographic (STL) files of the 3D model of the proposed TPU substrate were created with the aid of SOLIDWORKS 2020 software (Dassault Systems). The TPU substrate was printed through a fused deposition modeling (FDM) process using a MakerBot Replicator 2X Desktop 3D printer (MakerBot Industries, Brooklyn, USA) with a 0.4 mm inner diameter nozzle. Printing parameters were tuned based on dimensions and the smoothness of printed surfaces. TPU substrates were printed at an extruder nozzle temperature of 205° C., with a printing speed of 10 mm/s. The printing bed surface was covered with 3M™ scotch blue painter's tape (0.14 mm thickness) to improve the adhesion between the printed first layer and the printing bed surface.

In order to DIW the electrode, two different commercial printable silver pastes were purchased from Materials and DUPONT®, respectively. The first type of silver paste was DYCOTEC Materials DM-SIP-2002 mixed with DYCOTEC Materials DM-SIP-2002-DT at a volume ratio of 1:2 to prepare a stretchable conductor silver ink. The second type of silver paste was DuPont™ Intexar™ PE874 mixed with DuPont™ 8260 at a volume ratio of 1:2 to obtain another stretchable conductor silver ink. Next, both types of silver inks were printed, respectively, on the surface of FDM 3D printed thermal plastic polyurethane (TPU) substrates to obtain stretchable electrodes with the aid of a Hydra 16A 3D printer equipped with a syringe-based printing head (Hyrel3D SDS) at room temperature (25° C.). A fluid volume 1 ml syringe with a needle (18-gauge, outer Ø 1.27 mm and inner Ø 0.84 mm) loaded with the above-mentioned conductor ink was installed on the syringe-based printing head before the printing task. All the above-mentioned materials were used as received without any further modification except as noted.

The influence of the needle size on the electrically conductive continuity of DIW printed electrodes was studied systematically. Needles with eight different sizes were selected in this experiment, which are listed in Table 1. Needles of different sizes were tested by following the same experiment procedures, including printing designed electrode patterns and measuring printed lines' dimensions. The experiment procedures were described as follows in detail. First, a series of electrode patterns were printed through the DIW process using the same needle, during which all printing parameters were kept constant. The length (40 mm) and width (40 mm) of these electrodes' patterns are the same, except the distances of the center lines of any two adjacent printed lines are different. The distance of the centerlines of two adjacent printed lines is defined as line distance (mm) as shown in FIG. 1c, which is a schematic of lines DIW printed varying the spacing between printed lines. In this experiment, the shortest line distance in the designed patterns is 0.2 mm, and then the line distance from one pattern to the following pattern increased gradually following a fixed increment of 0.2 mm until the line distance reached 2.0 mm, which is the maximum. Besides line distance, gap width is defined as the distance between two boundaries that belong to two adjacent printed lines, respectively (see the definition in FIG. 1c). Overlap is defined as the percentage of the width of the overlap area divided by the line width. The above-defined terms are useful to quantify the quality of DIW printed electrodes' patterns, and these definitions are also visually illustrated in FIG. 1c.

Based on the design as mentioned above with step-increased line distances from one pattern to the next, for a given size needle, ten electrode patterns with the same dimension (40 mm×40 mm) but different line distances were printed. For the above-mentioned eight different-size needles, the printing procedures and the printed electrodes' patterns were the same. The line width, and line distance of the printed electrodes' patterns were carefully measured with a ZEISS Axioscope 5 optical microscope equipped with an Axiocam 305 color camera controlled by the ZEISS ZEN core v2.6 software.

TABLE 1
Colors and dimensions of different sizes of stainless-steel syringe needles

| | Needle size | | | | | | | |
|---|---|---|---|---|---|---|---|---|
| | 14- | 15- | 18- | 20- | 21- | 22- | 27- | 30- |
| | gauge | gauge | gauge | gauge | gauge | gauge | gauge | gauge |
| Color | olive | amber | green | pink | purple | blue | clear | lavender |
| Inner | 1.55 | 1.37 | 0.84 | 0.61 | 0.51 | 0.41 | 0.20 | 0.15 |
| diameter | | | | | | | | |
| [mm] | | | | | | | | |
| Outer | 1.83 | 1.65 | 1.27 | 0.91 | 0.81 | 0.71 | 0.41 | 0.30 |
| diameter | | | | | | | | |
| [mm] | | | | | | | | |

As discussed above two different commercial printable silver paste were obtained. Both types of silver inks were printed on the FDM 3D printed TPU substrate through DIW. Following the instructions from the datasheet of Dycotec Materials conductor silver paste, the Dycotec ink-printed electrodes should be annealed at a temperature in the range of 80° C. to 200° C. for 10 minutes. Three different temperatures (i.e., 120° C., 140° C., and 160° C.) were selected as the annealing temperature. It should be noted that the 3D printed TPU substrate is not ideally flat and has cornrow structures on the surface due to the filament melt-extrusion-solidification mechanism of the FDM 3D printing process. The direction of the cornrow structures was controlled by the infill directions of the FDM 3D printing process. Since the conductor ink was printed on FDM 3D printed TPU substrate, the infill directions of the 3D printed substrate can influence the performance of the DIW printed stretchable electrodes. Considering the influence of annealing temperatures, and the 3D printing infill directions, nine groups of samples were printed and there were six samples in each group to obtain data with statistical meaning. The sample preparation plan is listed in Table 2. Samples in the same group were printed on the substrate with the same infill direction and subjected to the same treatment (i.e., annealing). The dimensions of the 3D printed TPU substrate together with infill directions regarding the stretching load direction are shown in FIG. 1d, which is a schematic of an FDM 3D printed TPU substrate including the definition of infill direction.

TABLE 2
Experiment plans to test the performance of stretchable conductor inks

| Group # | Ink manufacturer | Substrate infill [°] | Annealing temperature [° C.] | Time [min] |
|---|---|---|---|---|
| 1 | Dycotec | 0 | 120 | 10 |
| 2 | Dycotec | 45 | 120 | 10 |
| 3 | Dycotec | 90 | 120 | 10 |
| 4 | Dycotec | 0 | 140 | 10 |
| 5 | Dycotec | 45 | 140 | 10 |
| 6 | Dycotec | 90 | 140 | 10 |
| 7 | Dycotec | 0 | 160 | 10 |
| 8 | Dycotec | 45 | 160 | 10 |
| 9 | Dycotec | 90 | 160 | 10 |
| 10 | DuPont | 0 | 130 | 15 |
| 11 | DuPont | 45 | 130 | 15 |
| 12 | DuPont | 90 | 130 | 15 |

The performance of the DIW printed stretchable silver electrodes were evaluated by measuring the conductivity of the electrodes during the stretching. First, the sample was clamped and fixed on a linear stretcher, which was used to apply stretching load manually. The initial conductivity of the sample was measured by an Inductance Capacitance Resistance (LCR) meter (NF ZM 2372) on a logarithmic scale, in a frequency range from 1 to 105 Hz at room temperature (25° C.). Then, the sample was stretched step by step at a fixed increment of 2 mm. During each stretching distance interval, the conductivity of the printed electrodes was measured and recorded with the aid of an inductance-capacitance-resistance (LCR) meter. Finally, the measurement results were plotted to obtain the variation of resistivity as a function of stretching distance at a constant frequency (e.g., 1 kHz), as discussed further below.

Once the DIW parameters have been optimized for printing the electrode line-by-line on the TPU substrate, next the electrospinning process is optimized. This optimization is based on maximizing the β-phase by modifying four electrospinning parameters: the voltage applied to the syringe needle (see FIG. 1b), the concentration of the polymer solution 204 (see FIG. 1b), the flow rate of the polymer solution 204 (see FIG. 1b) out of the syringe 202, and time. Adjusting these parameters affects the morphology of the microstructure of the PVdF, insofar as fiber diameter, bead diameter, closeness of fibers and beads to each other, etc.

PVdF pellets (Mw=275,000), N, N-dimethylformamide (DMF), and acetone were purchased from SIGMA-ALDRICH INC., USA. The DMF and acetone were mixed following a DMF: acetone volume ratio of 4:6, as a solvent. PVdF pellets were dissolved in the DMF/acetone (4/6 v/v) solvent mixture to prepare a PVdF solution with a concentration of 15 wt. %, and the mixture was magnetically stirred at 67° C. for 3 h to obtain a transparent solution.

A lab constructed electrospinning setup was used for electrospinning. The PVdF solution was loaded in a 5 mL plastic syringe capped with a 21-gauge steel needle (inner diameter 0.8 mm, needle length 1.27 cm) for electrospinning. The solution flow rate was controlled by a syringe pump (KD SCIENTIFIC) at 0.51 mL/h. A high voltage was applied to the needle through a DC power supply (Gamma High Voltage). An aluminum flat plate (diameter 10 cm) was grounded and used as the collector 218 (see FIG. 1b).

Surface morphology was observed on a scanning electron microscopy (SEM, Phenom ProX). The fiber diameter was measured based on SEM images using image processing software (ImageJ 1.45s).

FTIR analysis was conducted within the wavenumber range from 600 to 1300 cm⁻¹ through NEXUS 670 FTIR to characterize the microstructure of 3D printed PVdF films in the air at room temperature (25° C.). The mechanical properties of electrospinning PVdF microfiber membrane were tested on an ADMET eXpert 2600 series of dual-column electromechanical universal testing systems with a crosshead speed of 12 mm/min at room temperature (25° C.). Up to six specimens for each group were tested. The preload was controlled at about 2.5×10-4 MPa.

Next, the DIW process was combined with the electrospinning process. DIW was applied to print stretchable conductor ink on electrospinning PVdF microfiber membrane to metalize the transducer materials' surface with designed electrodes' patterns. DIW printing process is critical to building electrospinning PVdF-based force/pressure sensors or transducers. However, the porous nature of the electrospinning PVdF microfibers as the substrate for DIW printing can cause the leakage of the conductive ink through the fibrous matrix, leading to electrical shorting between the printed electrodes. Therefore, the key to succeeding in the fabrication of electrospinning PVdF-based sensors is to print silver electrodes on both sides of the microfiber membrane without a short circuit. Since leakage is related to the surface morphology (i.e., the size distribution of microfibers and beads) and the layer thickness of the electrospinning PVdF microfiber membrane. The surface morphology and the thickness are mainly controlled by electrospinning parameters including the voltage potential between the needle and the grounded collector plate (V), the flow rate of the electrospinning solution (mL/h), the concentration of the solution (wt. %), and the time (h). Thus, experiments were conducted to study the influence of the above-mentioned electrospinning parameters on the yield of the sensor. The yield of the sensor was defined by fabricating a given number of sensors (e.g., 20 according to the present disclosure) and measuring the number of sensors without a short circuit between the top and bottom electrodes. The yield is directly positively related to the possibility of electrical shorting between the printed electrodes. During the experiment, only one parameter was adjusted while keeping other parameters fixed all the time. For instance, different levels of voltage potentials (i.e., 10 kV, 15 kV, 20 kV, and 25 kV) were selected to study the influence of the voltage potential on the yield while other parameters were kept constant. The electrospinning parameters in this study are listed in Table 3.

TABLE 3
Electrospinning parameters for PVdF microfibers

| | Voltage | Flow rate | Concentration | |
|---|---|---|---|---|
| Group # | [kV] | [mL/h] | [wt. %] | Time [h] |
| 1 | 10 | 0.51 | 15 | 1 |
| 2 | 15 | 0.51 | 15 | 1 |
| 3 | 20 | 0.51 | 15 | 1 |
| 4 | 25 | 0.51 | 15 | 1 |
| 5 | 15 | 0.25 | 15 | 1 |
| 6 | 15 | 0.51 | 15 | 1 |
| 7 | 15 | 1.00 | 15 | 1 |
| 8 | 15 | 1.75. | 15 | 1 |
| 9 | 15 | 0.51 | 0.90 | 1 |
| 10 | 15 | 0.51 | 1.20 | 1 |
| 11 | 15 | 0.51 | 0.51 | 1 |
| 12 | 15 | 0.51 | 1.80 | 1 |
| 13 | 15 | 0.51 | 15 | 1 |
| 14 | 15 | 0.51 | 15 | 2 |
| 15 | 15 | 0.51 | 15 | 3 |
| 16 | 15 | 0.51 | 15 | 4 |

The procedures to determine the yield under a specific combination of electrospinning parameters are described as follows in detail as shown in FIG. 1e, which is a schematic showing printed electrode on PVdF microfiber structure, where parts of the printed electrodes show electrical shortage. After performing electrospinning following a given combination of electrospinning parameters, a layer of electrospinning PVdF microfiber membrane was obtained. A series of square shape silver electrodes (2.54 cm×2.54 cm) was printed on the surface of the PVdF microfiber membrane. The distances between these square shape electrodes were equal to 2.54 cm. After the printing, the areas on the surface of the electrospinning PVdF membrane were automatically classified into three types: (1) printed electrodes without short circuit area, (2) Printed electrodes with short circuit area, and (3) no printed electrodes area. A multimeter was used to check the electrical shorting between the DIW printed top electrodes and the aluminum collector electrode. The yield rate was calculated by using the number of printed electrodes without shorting divided by the number of printed electrodes in total as shown in FIG. 1e.

The structure of the proposed electrospinning PVdF-based pressure transducer contains an electrospun PVdF microfiber membrane sandwiched between two DIW printed silver electrodes on the top and bottom sides and deposited on a TPU substrate, respectively. Silver electrodes were printed by using above-mentioned stretchable silver conductor inks through the DIW process. Printing parameters were tuned based on dimensions and the smoothness of printed electrodes. The silver inks were printed at a printing speed of 800 mm/min at an extruder nozzle temperature of 25° C.

Next, the transducer's output was characterized on a lab made mechanical input working station and a low-noise current preamplifier (Model SR570, Stanford Research Systems). Different compression forces from 1 to 10 N were applied at a frequency of 0.5 Hz to investigate the relationship between applied forces and the transducers' outputs. The transducers' durability test was also performed by using the same test platform.

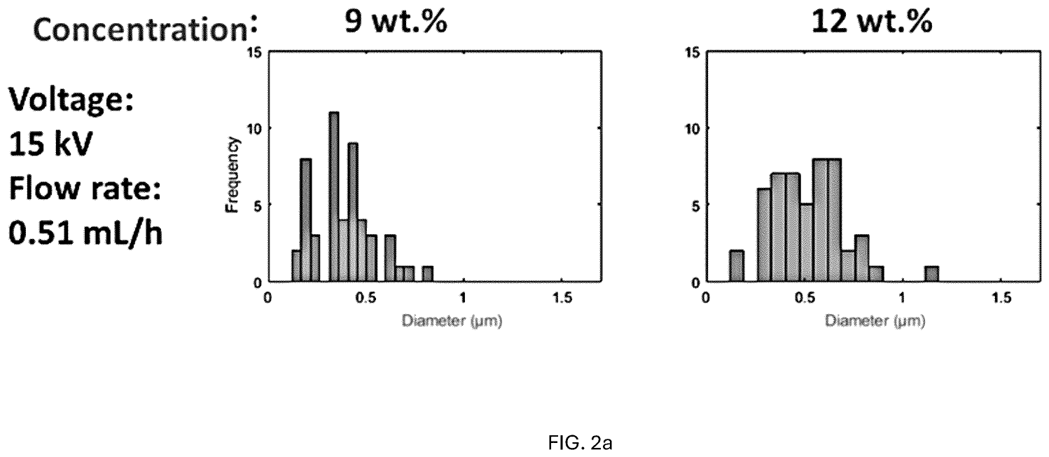

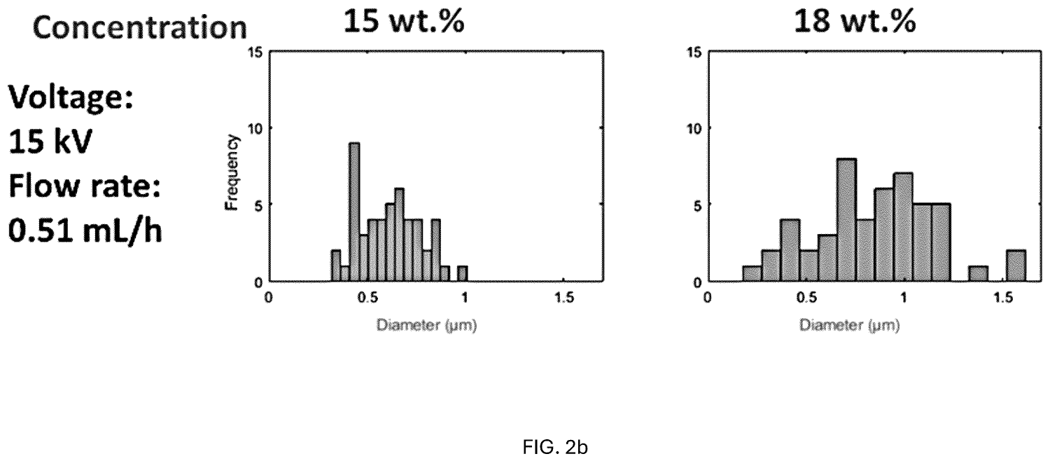

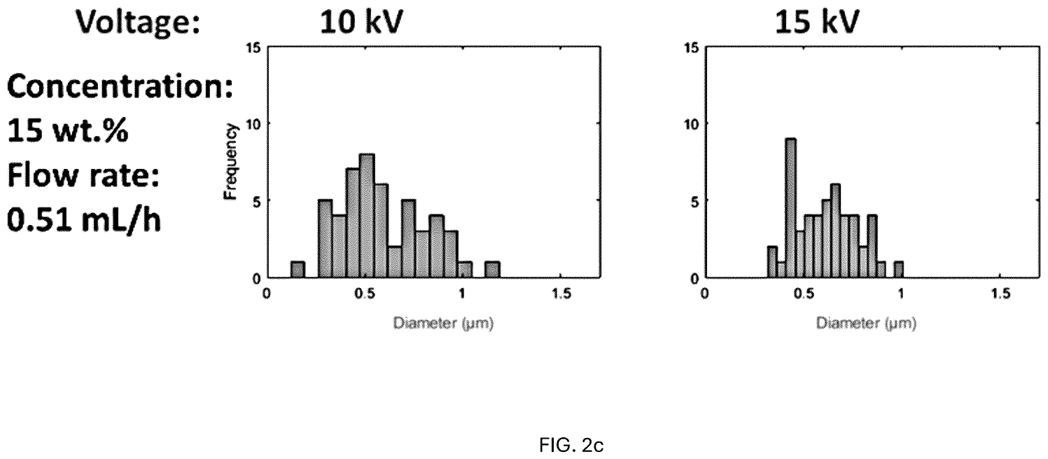

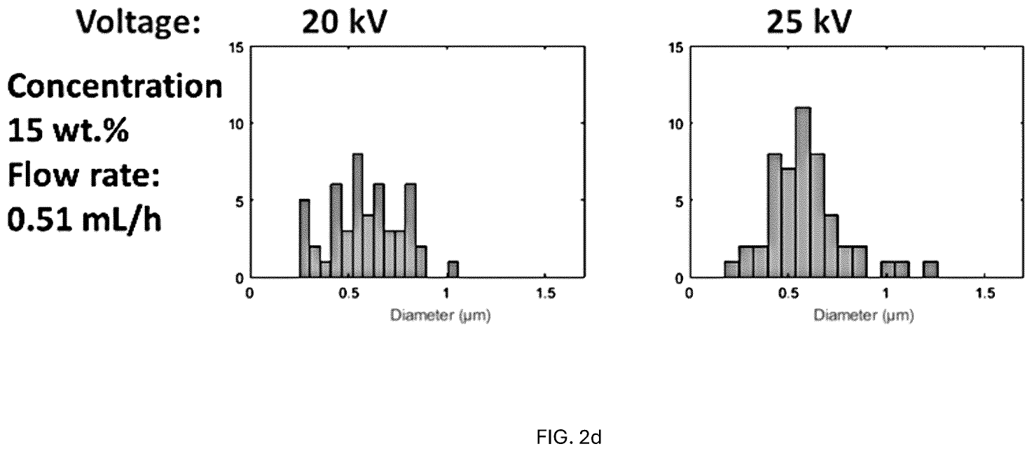

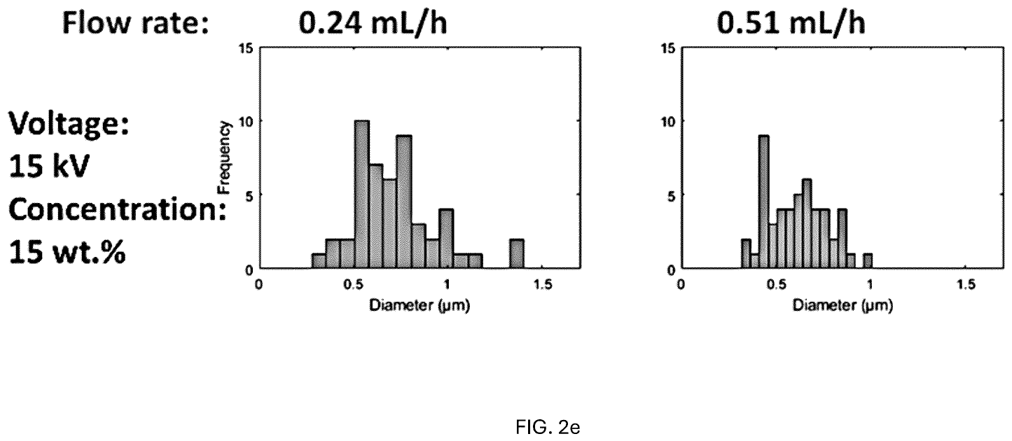

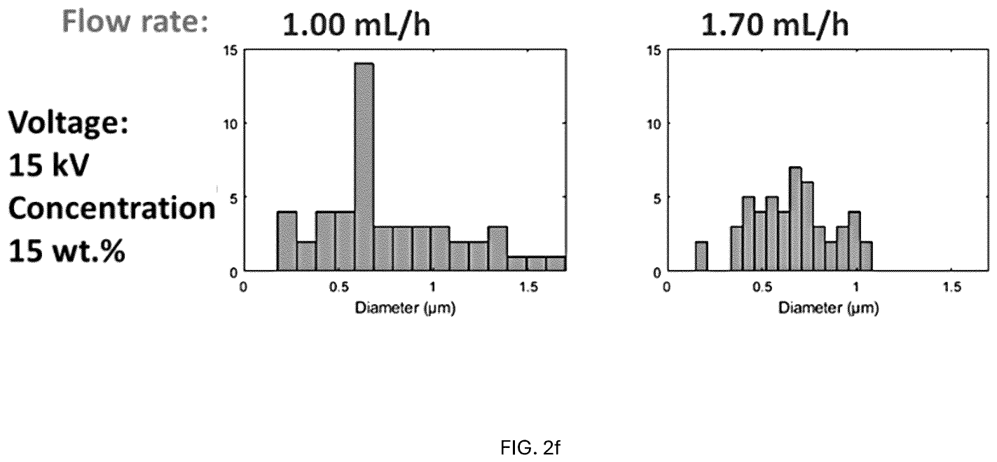

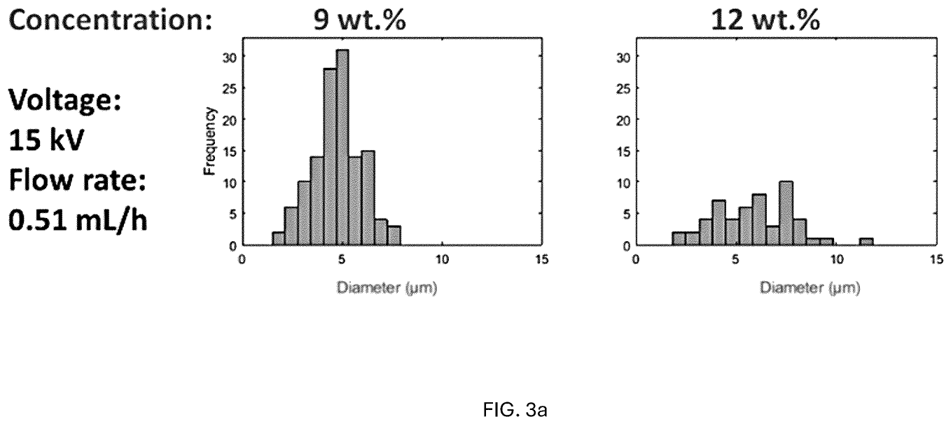

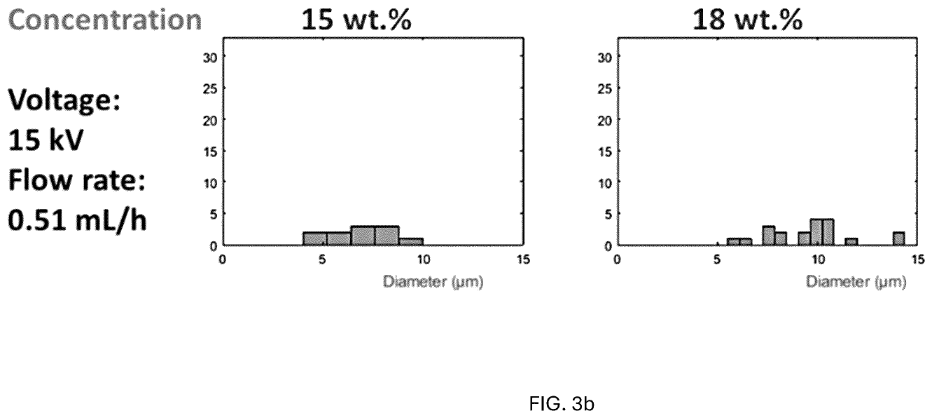

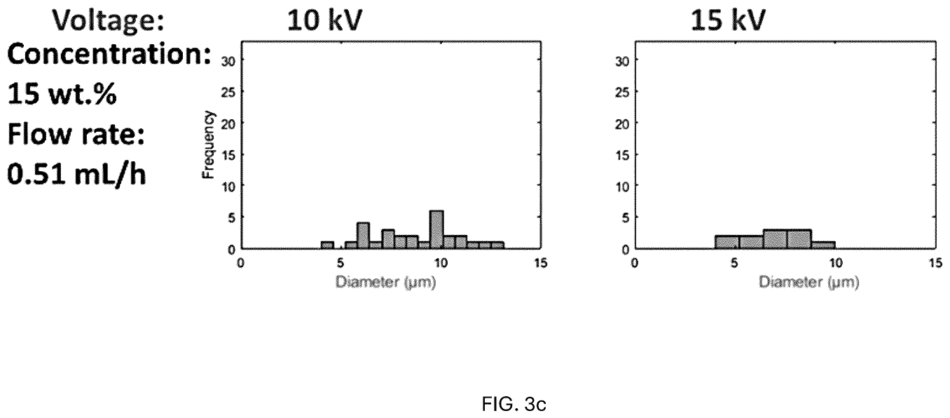

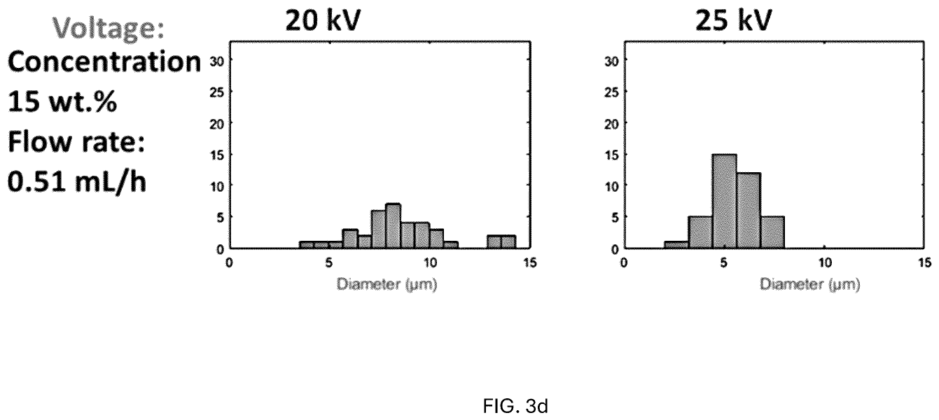

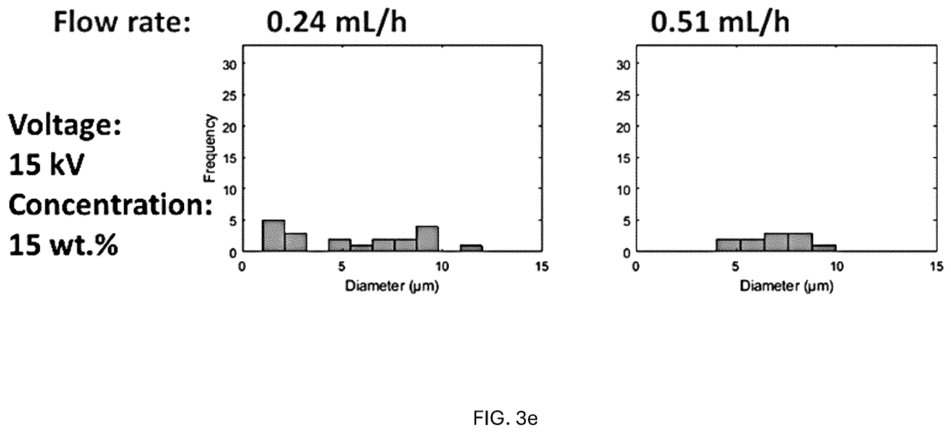

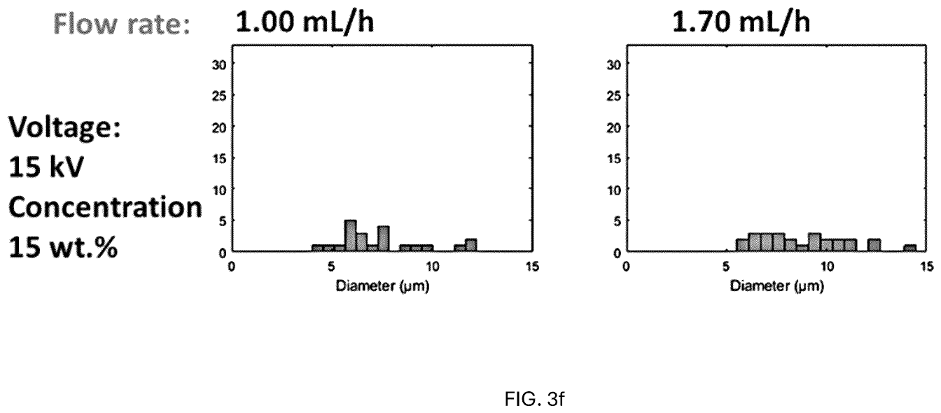

The effects of varying the above-mentioned four electrospinning parameters on surface morphology including the size distributions of microfibers and microbeads were studied and the results are shown in FIGS. 2a-2f and FIGS. 3a-3f, which are graphs of influence of electrospinning parameters including voltage, concentration of the solution, and flow rate on the size distribution of PVdF microfibers (FIGS. 2a-2f) and graphs of influence of electrospinning parameters including voltage, concentration of the solution, and flow rate on the size distribution of PVdF beads (FIGS. 3a-3f), respectively. The surface morphology was mainly determined by voltage, solution concentration, and solution flow rate. The influence of all three parameters were studied separately by only adjusting one parameter (e.g., flow rate) with four different levels (e.g., 0.24 mL/h, 0.51 mL/h, 1.0 mL/h, and 1.70 mL/h) and keeping other parameters as constant. A static stainless-steel plate with aluminum foil placed served as a grounded collector electrode (see 218 in FIG. 1b). The voltage potential between the syringe needle and the collector plate was controlled by the high voltage power supply (see 216 in FIG. 1b). The solutions were transferred to a 5 mL plastic syringe (see 202 in FIG. 1b). The polymer solution (see 204 in FIG. 1b) flow rate was maintained at 0.51 mL/h and the applied voltage potential between the syringe needle and collector were set at 15 kV with a tip-to-collector distance of 15 cm. All experiments were performed at room temperature (25° C.).

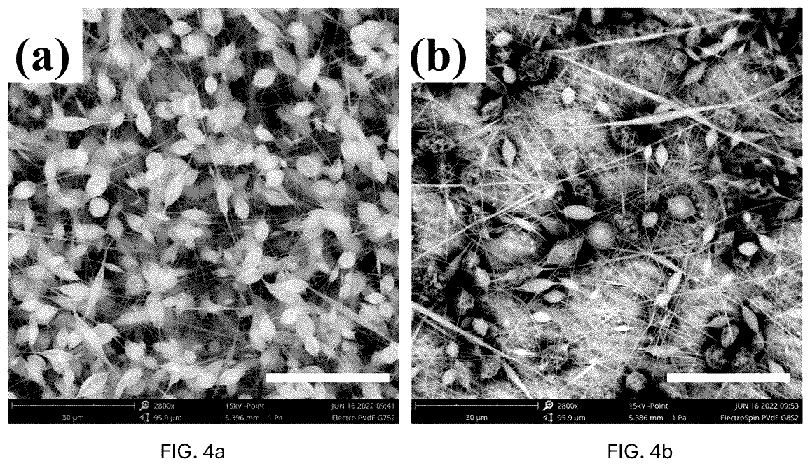

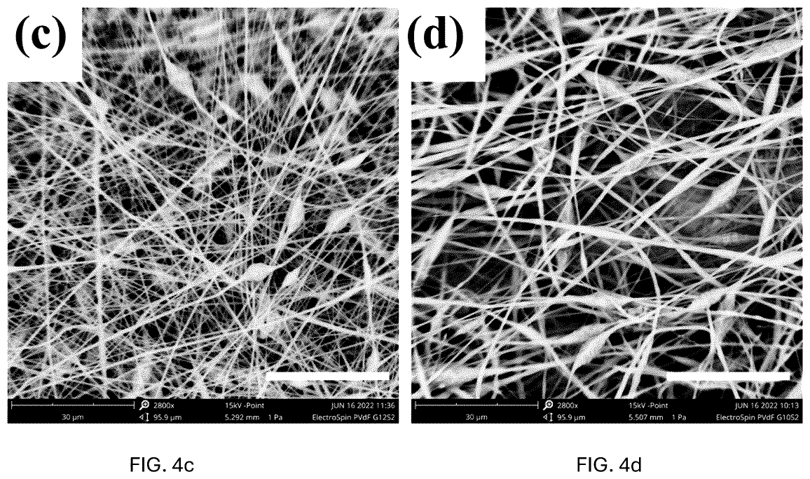

As discussed above, the polymer concentration is one of the parameters in the electrospinning solution that can affect the electrospinning process and surface morphology. According to the present disclosure, different concentrations of PVdF solutions were prepared including 9 wt. %, 12 wt. %, 15 wt. %, and 18 wt. % for electrospinning. The SEM images of electrospinning PVdF microfibers produced by using different solution concentrations are shown in FIGS. 4a-4d, which are SEM images of electrospinning PVdF microfibers produced by different solution concentrations: (a) 9 wt. %, (b) 12 wt. %, (c) 15 wt. %, and (d) 18 wt. %. (Scale bar: 30 μm), wherein the statistical results including the size distribution of microfibers and microbeads are shown in FIGS. 2a-2f and 3a-3f, respectively. When the solution concentration is lower, the size distribution was located within a range from a few hundred nanometers to 1 micrometer. However, beaded structures formed with a size distribution in the range from 1 μm to 7 μm. The reason was the surface tension-dominated instability effect. When the solution concentration was increased to 12 wt. % and then went up to 15 wt. %, the surface tension-dominated instability is slightly inhibited, leading to the formation of beads-on-fibers structures, and the reason is explained by the competition between the surface tension and the electric force-dominated stretching effect. During electrospinning, the polymer jet is formed when the extruded polymer solution subjects to strong electric field. Since PVdF materials are electrically active polymers, the extruded polymer solution is positively charged. The increasing of PVdF concentration at a fixed flow rate increases the mass of PVdF materials, which increases the solution's ability to carry more positive charges. The increasing number of positive charges increases the electrical propulsion force among these flying fibers. The electrical propulsion force tends to stretch these flying fibers into fiber-like geometries and that is electrical stretching effect. The electrical stretching effect competes with surface tension, which tends to hold the solution as sphere shapes, just like beads. The size distributions of microfibers produced by using 12 wt. % and 15 wt. % solutions were in the range of 0.2 μm to 1.2 μm and the range of 0.3 μm to 1 μm, respectively. If the concentration is further increased to 18 wt. %, the polymer chain entanglement can compete with the instability, leading to continuous fibers which means the size distribution of microfibers became wider which included fibers with size distributed in the range of 0.2 μm to 1.6 μm

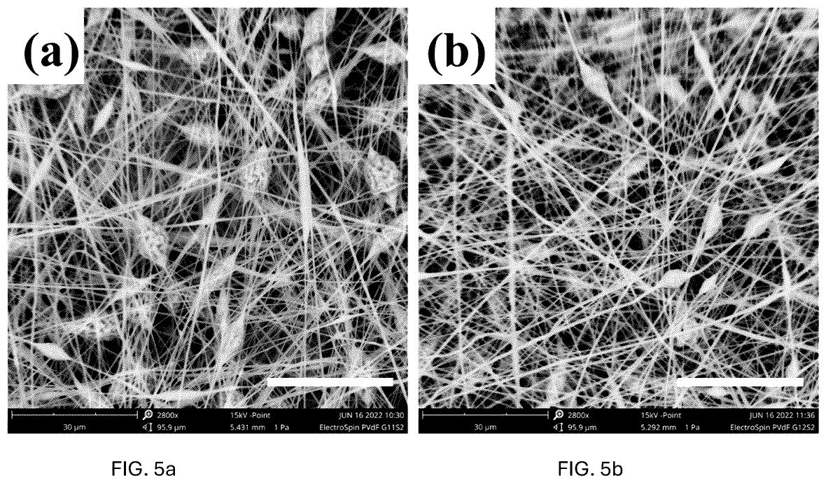

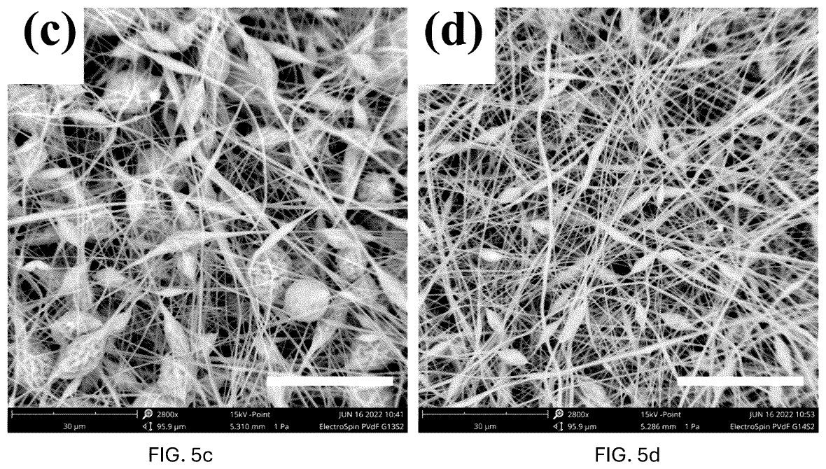

As discussed above, the applied voltage is another electrospinning parameter that can affect morphology of the generated PVdF. Thus, different levels of voltage (i.e., 10 kV, 15 kV, 20 kV, and 25 kV) were selected while other parameters were kept as constant. The SEM images of electrospinning PVdF microfibers produced by using different voltages are shown in FIGS. 5a-5d, which are SEM images of electrospinning PVdF microfibers produced by different voltage potentials between the needle and the collector: (a) 10 kV, (b) 15 kV, (c) 20 kV, and (d) 25 kV. (Scale bar: 30 μm), and the statistical results including the size distribution of microfibers and microbeads are shown in FIGS. 2a-2f and 3a-3f, respectively. During the electrospinning process, the electric field strength controlled electrical stretching effect has a major influence on the surface morphology. The average fiber diameter decreases with the increasing of applied voltage due to the increased electrical forces applied on the polymer solution to stretch the polymer solution to form microfibers. With the increasing of voltage, the size distribution curves became narrow, which means the fiber diameters not only decreased but also became more uniform. Interestingly, higher voltage values induced the formation of beads, due to the increase in the electrical forces applied on the polymer solution. The higher the voltage applied the faster the droplets moved towards the plate electrodes and the less time for the solvent to evaporate before the droplets deposited on the collectors. The wet fibers and droplets can merge together before the solvent evaporated thoroughly, which explained the appearance of large number of beads at high electrospinning voltage (25 kV).

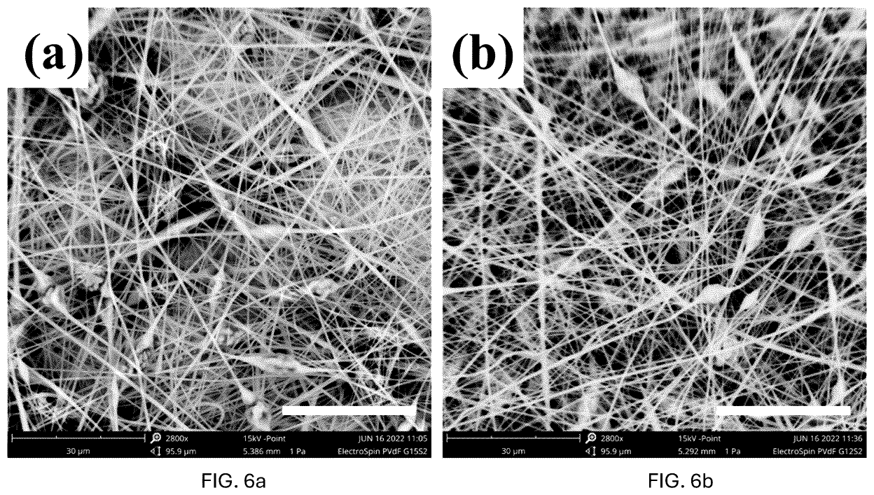

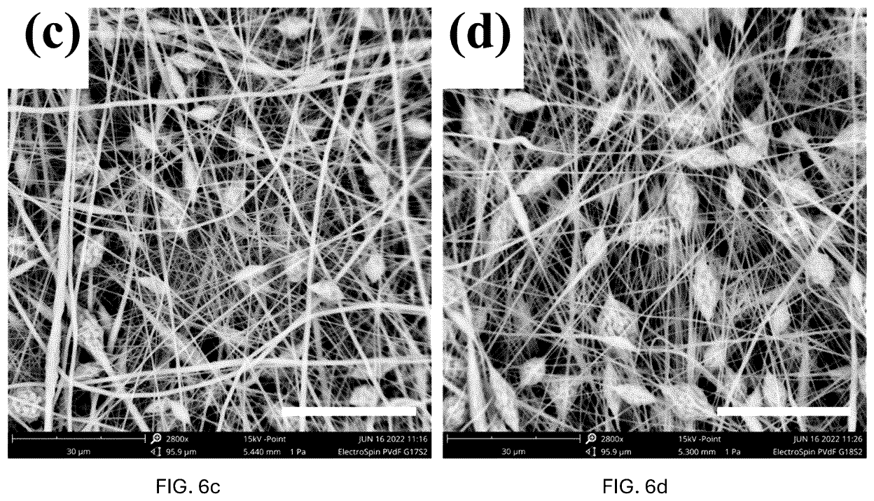

Flow rate of the polymer solution is yet another parameter that can affect the morphology of the PVdF. Thus, various flow rates were studied, according to the present disclosure. The SEM images of electrospinning PVdF microfibers produced by setting different flow rates are shown in FIGS. 6a-6d, which are SEM images of electrospinning PVdF microfibers produced by different flow rates: (a) 0.24 mL/h, (b) 0.51 mL/h, (c) 1.0 mL/h, and (d) 1.70 mL/h. (Scale bar: 30 μm), and the statistical results including the size distribution of microfibers and microbeads are shown in FIGS. 2a-2f and 3a-3f, respectively. From the results shown in FIGS. 2a-2f, increasing the flow rate results in an increasing trend in the average fiber diameter, due to the increasing mass of materials extruded within a unit time. Nevertheless, beads are observed at either low or higher flow rates, inducing a loss of fiber uniformity. In the first case (i.e., average fiber diameter), the increase is related to an increase in the surface tension of the solution during the flying process, whereas in the second case (i.e., presence of beads), it is due to insufficient time for the solvent to evaporate completely. The microfibers produced under 0.24 mL/h conditions have a morphology with many large-size beads distributed in the range from 1 μm to 12 μm. The formation of beads can occur when the wet polymer fibers deposited on the collector merged and the size of the bead grew with the assistance of the surface tension. As the flow rate increased, the volume of polymer solution extruded passed through the cross-section area of the needle within a unit of time increased. When more materials were extruded at a given time (i.e., at 0.51 mL/h flow rate), the size of electrospinning microfibers produced increased, but there was a distinct decrease in the number of beads. At 0.51 mL/h flow rate, the morphology of the fibers produced becomes more uniform and the number of beads decreases. The phenomenon is due to the competition between surface tension and the electrical stretching effect. During the electrospinning process, the extruded polymer solution was electrically charged. Thus, the flying microfibers can interact with each other through electric static forces. Before the wet polymer fibers arrived at the collector electrodes, the electric static forces among these fibers can cause the deformation of these fibers. With the increasing flow rate, more materials were extruded and the interactions among different fibers through electric static forces were enhanced. The electric static forces can regulate the size of microfibers and make the size distribution tend to be more uniform.

In summary, electrospinning parameters can interact together to have a complicated influence on the surface morphology of PVdF microfibers. The size distributions of both microfibers and microbeads did not show a monotonic variation trend when simply adjusted any one of electrospinning parameters from low to high. For instance, with the decreasing of the voltage, the size of fibers decreased and then increased. Therefore, determining optimal values for the polymer jet formation and controlling fiber size distribution requires an optimization process.

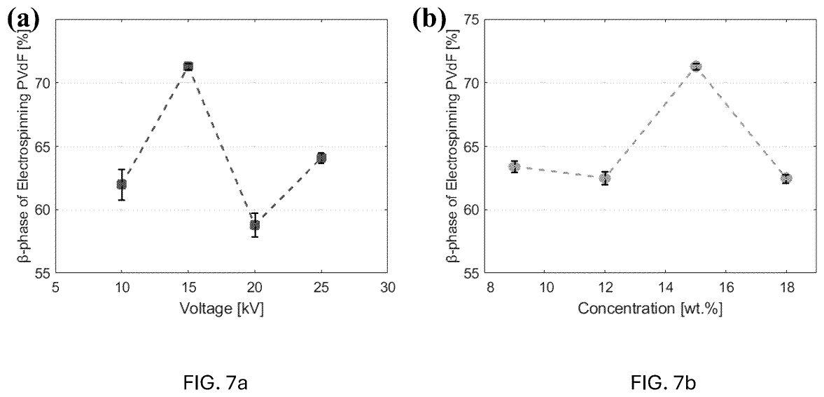

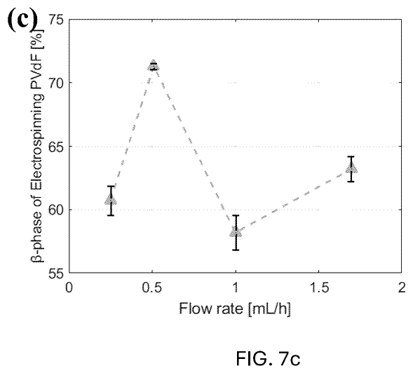

Resulted PVdF materials have five different crystal phases with three different chain conformations: all trans (TTTT) conformation for β-phase, trans-gauche+-trans-gauche-(TGTG′) for α and δ-phases and T3GT3G′ for γ and ε-phases. Thermally stable α and γ-phases are commonly found in PVdF materials, whereas β-phase has the highest net dipole moment in a unit crystal cell which is mainly responsible for the transducer output characteristics. The β-phase content was calculated according to the FTIR result. FIGS. 7a-7c, which are graphs of β-phase of electrospinning PVdF (in %) vs. voltage in KV, concentration in wt. %, and flow rate in ml/h, respectively, show the influence of voltage, polymer solution concentration, and flow rate on the β-phase content of electrospinning PVdF microfibers. The results were measured by varying only one parameter and keeping constant all other parameters. For instance, a typical combination (as default) of the electrospinning parameters is listed as follows: voltage 15 kV, flow rate 0.51 mL/h, solution concentration 15 wt. %, and time 4 h. When studying the influence of solution concentration, four different levels of solution concentration (i.e., 9 wt. %, 12 wt. %, 15 wt. %, and 18 wt. %) were prepared and used for electrospinning individually and the rest of parameters were kept as constant.

First the effect of voltage on of β-phase of electrospinning PVdF is discussed. Conventionally, the polymer chain conformation in crystalline region of PVdF materials is mainly α-phase. The phase transformation from α-phase to β-phase is implemented by stretching the sample film in the length direction while applying a strong electric field (e.g., 50 MV/m) in parallel with the sample thickness direction. The electrical stretching effect and the whipping movement of the polymer jet caused by the application of a strong electric field during the electrospinning process can stretch the polymer chain and orient dipoles in the PVdF molecular chains, allowing the amorphous-to-crystalline region transformation. The polymer chain conformation in the crystalline region of PVdF formed under a strong electric field tends to be β-phase conformation.

As shown in FIG. 7a, with the increasing of applied voltage from 10 kV to 15 kV, the β-phase content increased from 62.3% to 72.0%. This trend was attributed to two effect factors: the strength of the applied electric field and the whipping movement of the polymer solution jet. When the voltage was 10 kV, low electric field strength resulted in coarse fibers with low β-phase content (see the fiber diameter distribution in FIGS. 2c-2d). Increasing the applied voltage enhanced the electric field strength which led to higher electrostatic forces to stretch the jet during electrospinning. With increasing of the applied voltage from 10 kV to 15 kV, the average fiber diameter decreased from 10.0 μm to 6.5 μm. Meanwhile, the β-phase content increased. Further increasing the applied voltage from 15 kV to 20 kV caused the fiber diameter to increase to 7.8 μm and β-phase content decreased. When the applied voltage reached 20 kV, the higher applied voltage resulted in higher fiber deposition speed, causing shorter time for whipping movement, which means less time for the solvent to evaporate. More solvent remained in the fibers deposited on the collector surface. Fibers with solvent remained were easy to collapse to form coarse and interconnected fibers, which showed beads-on-fibers morphology. Most PVdF microfibers tend to form α-phase conformation. When the applied voltage is further increased up to 25 kV, the electric poling effect caused by the strong electric field between the needle tip and the collector surface can align dipoles of deposited PVdF microfibers. The β-phase content increased to 64.8% at 25 kV.

Second, the effect of polymer solution concentration on of β-phase of electrospinning PVdF is discussed. When the concentration of the polymer solution increased from 9 wt. % to 15 wt. %, the electrical stretching effect from the electric field on the polymer solution increases, so the β-phase content increased gradually, as seen in FIG. 7b. While the PVdF concentration increased to a critical value, the extruded polymer solution experienced the most significant stretching effect at the same the electric field strength. The electrospinning PVdF microfibers showed the maximum β-phase content. Further increasing the PVdF concentration increased the viscosity of the solution. At the same electric field strength, the electric force cannot effectively stretch the polymer solution to have fiber-like geometries as before due to the robust polymer chain entanglement effect. Large beads which have sizes distributed in the range from 5 μm to 14 μm appeared. When the electrical stretching effect was inhibited, the polymer chain cannot be effectively stretched to take β-phase conformation, which is the most extended polymer chain conformation in PVdF. Therefore, when the PVdF concentration reached 18 wt. %, the β-phase content decreased.

Finally, the effect of flow rate of the polymer solution on β-phase of electrospinning PVdF is discussed. From the results shown in FIG. 7c, the flow rate also has an important effect on β-phase content. Increasing the flow rate from 0.25 mL/h to 0.51 mL/h, the β-phase content increased from 61.0% to 71.8%, due to the formation of a stable polymer jet and the whipping movement of the jet during the electrospinning. The β-phase content decreased to 58.0% at the flow rate of 1 mL/h and then went up for a second time to read 63.8% at the flow rate of 1.70 mL/h. The increased volume of solution can enhance the interaction among flying fibers through electric forces. As discussed above, during electrospinning, flying fibers were positively charged. There was an electric propulsion effect existed among them, which can also stretch the flying fibers to form fibers on a microscale. Besides, an increase in the flow rate caused a rapid deposition of fibers on the collector and insufficient time for the solvent to evaporate. The presence of solvent limited the formation of β-phase conformation in the crystalline region of PVdF materials due to the lack of stretching effect which is important to transfer other polymer chain conformations to the most extended polymer chain conformation, namely β-phase conformation. In short, the solvent evaporation effect and the stretching effect competed to influence the β-phase content in the final PVdF microfibers.

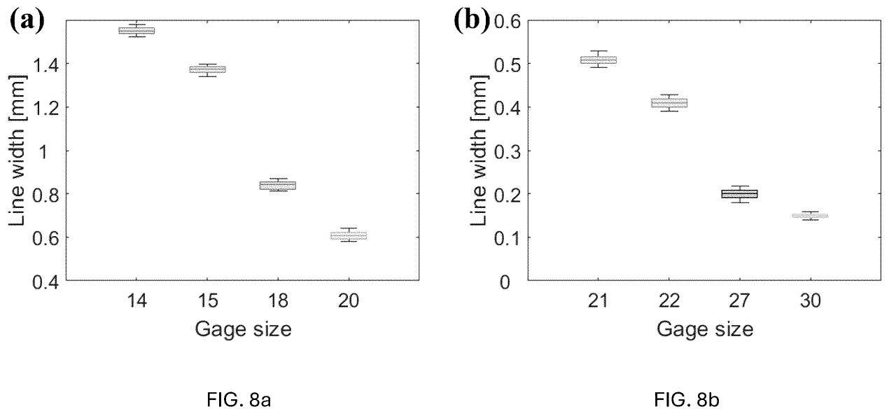

Having discussed effects of electrospinning parameters on β-phase conformation in the crystalline region of PVdF materials, next the effects of parameters on DIW for the printed electrodes are now discussed. The width of DIW printed lines by using different size of needles were measured and the results are shown as box plots in FIGS. 8a and 8b, which are graphs of line width in mm vs. gauge size of the DIW needle (note the needle referred to is not the needle of the syringe shown in FIG. 1b, but rather a needle of the 3D printing setup for DIW printing of electrodes). For a given size of a needle, the inner diameter must be a fixed value following the manufacturing standard. For instance, a 14-gauge needle has an inner Ø1.55 mm and an outer Ø1.83 mm. The width of printed lines using a given size of the needle is mainly controlled by the inner diameter of the needle. The variations of the width compared with the inner diameter are caused by DIW printing parameters. Typical DIW printing parameters include the printing speed, viscosity of the ink, surface energy of the substrate, and the distance between the needle tip and the substrate. These printing parameters can interact together to have a complex influence on the printed line width. In this research work, the influence of needle size on the width of printed lines was studied while all other above-mentioned printing parameters were kept constant. The measurement results shown in FIGS. 8a and 8b prove that the mean value of the line width was determined by the inner diameter of the corresponding needle. The variations (i.e., the maximum and the minimum) are in the range of +0.03 mm for lines printed by needles of 14-gauge, 15-gauge, 18-gauge, and 20-gauge. The variations of the line width printed by using needles of 21-gauge, 22-gauge, and 27-gauge are within +0.02 mm. The finest lines were printed by using a 30-gauge needle, which has a variation of +0.01 mm.

For a given size of needle, under fixed printing parameters, the printed line width together with the above defined line distance can determine the overlap of two adjacent lines which can finally determine the electrically conductive continuity of printed electrodes. When the overlap is zero, the printed electrodes lose the electrically conductive continuity. For a given needle, the line distance in the designed electrodes' patterns should be set properly to guarantee using the selected needle and printing under pre-determined printing parameters and following the designed printing path can succeed in printing designed electrodes' patterns without losing electrically conductive continuity. An important condition for printing is to control the overlap between adjacent lines properly. Small overlap leads to printed electrodes losing electrically conductive continuity. However, large overlaps can increase the printing time and most importantly waste a large volume of ink, especially in the case of large-scale manufacturing in industry. In short, the line distance in the designed electrodes' patterns is significantly important to determine the printing results including the electrically conductive continuity, printing time, and ink volume needed.

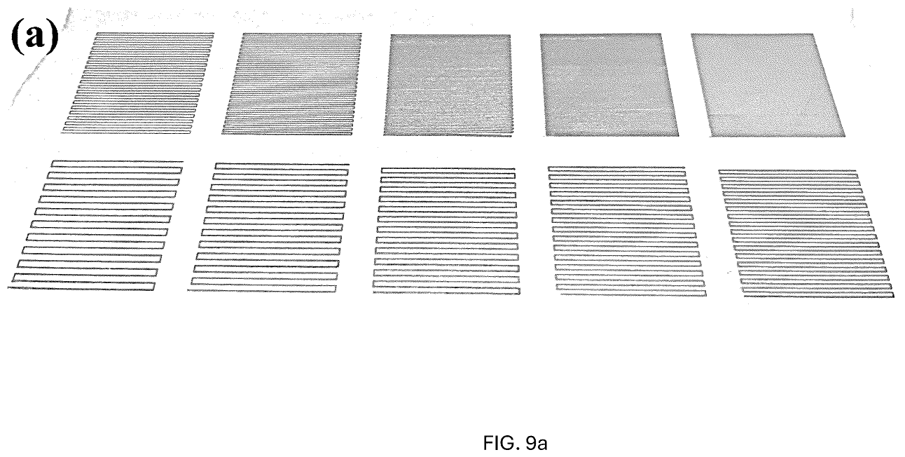

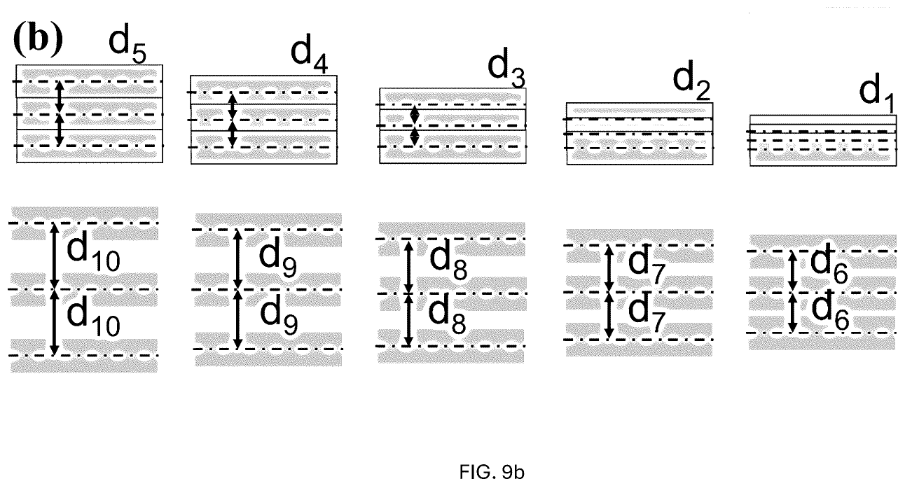

The effects of the line distance on the overlap of two adjacent lines were studied and the results were described as follows. A series of representative DIW printed electrodes' patterns with different line distances (d, mm) printed by using a 27-gauge needle are shown in FIG. 9a, which is a schematic of DIW printed silver electrodes (40 mm×40 mm) with different line distances in designed electrodes' patterns. All electrodes' patterns have the same dimension (i.e., 40 mm×40 mm). The only differences in the design of these printed electrodes' patterns are the line distances which are marked as the letter “d” with different subscript numbers depicted by a schematic in FIG. 9b, which is a schematic of different lines' distances in electrodes' patterns corresponding to the printed electrodes in FIG. 9a. The exact values of these lines' distances are listed in Table 4.

TABLE 4
Lines' distances in the design of DIW printed electrodes' patterns

| | Line distances | | | | | | | | | |
|---|---|---|---|---|---|---|---|---|---|---|
| | d₁ | d₂ | d₃ | d₄ | d₅ | d₆ | d₇ | d₈ | d₉ | d₁₀ |
| Distances [mm] | 0.2 | 0.4 | 0.6 | 0.8 | 1.0 | 1.2 | 1.4 | 1.6 | 1.8 | 2.0 |

From the results shown in FIGS. 9a and 9b, with the decreasing of the line distances, the boundary of two adjacent lines moved closer, which means the gap width decreased. The gap width is the distance of two closest boundaries belonging to two adjacent lines separately, which is controlled by both the line distance and the needle size. The overlap area was zero before the “contact” of the boundary of two adjacent lines. The overlap area started to increase after the line distances reached a specific value which is defined as the threshold value in this experiment. After the line distances reached the threshold value, the overlap increased with the decreasing of the line distance.

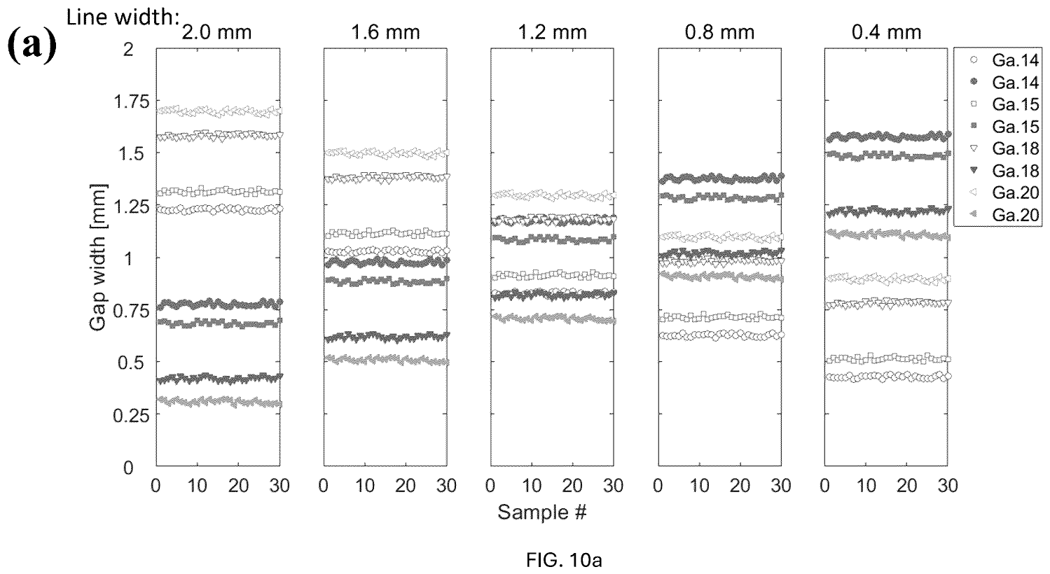

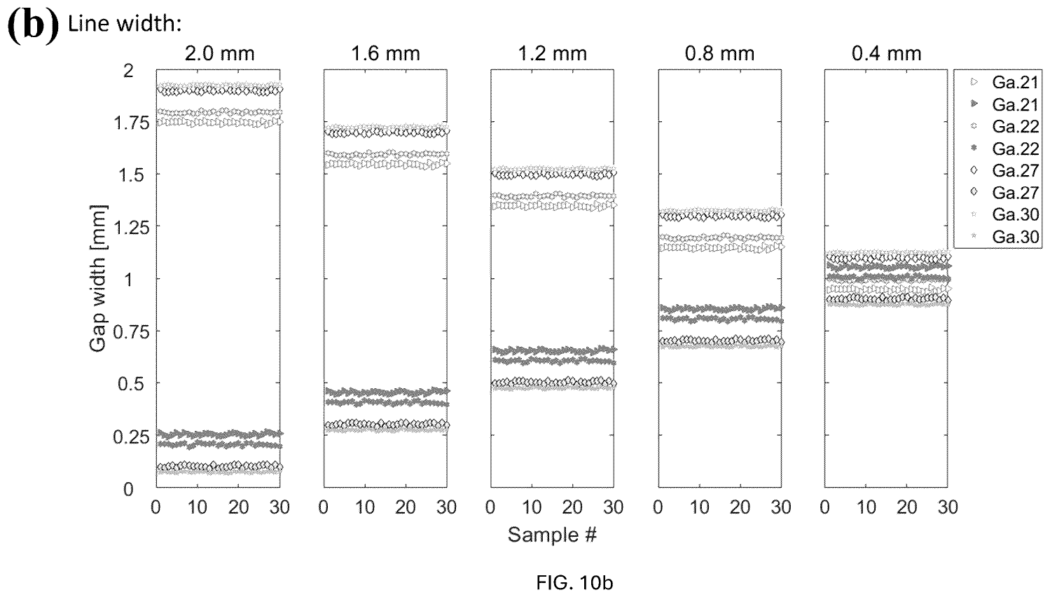

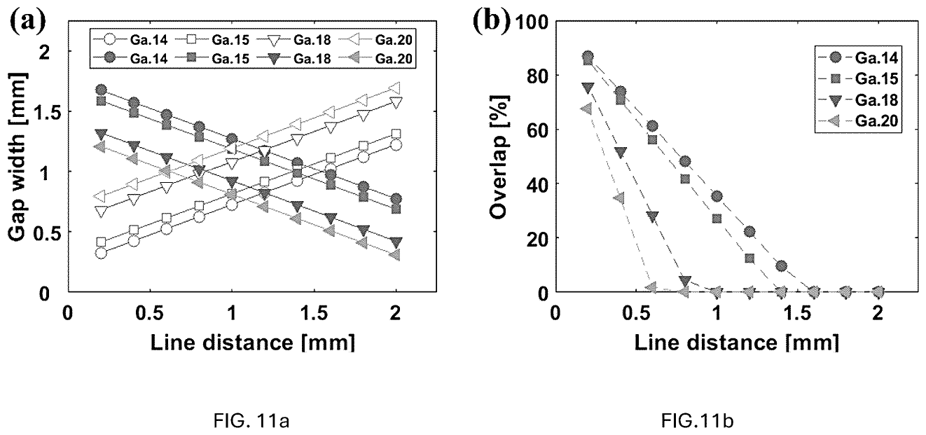

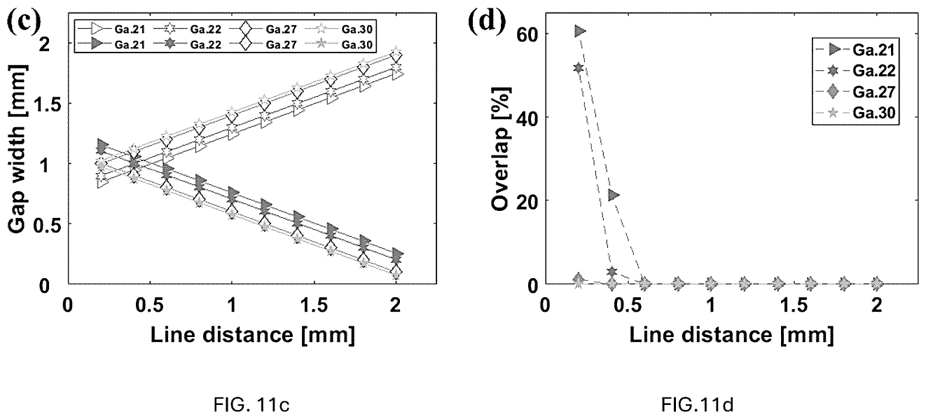

To quantify the above-mentioned findings, the measurement results of the line width printed by different size of needles (shown in FIGS. 8a and 8b) and the dimensions of the designed electrodes' patterns (shown in FIGS. 9a and 9b) were used to calculate the variations of gap width as a function of line distance. The results were plotted and shown in FIGS. 10a and 10b, which are calculated variations of the gap width of DIW printed lines with the decreasing of the line distances based on different size of needles, wherein FIG. 10a is related to 14-gauge, 15-gauge, 18-gauge, and 20-gauge needles, and FIG. 10b is related to 21-gauge, 22-gauge, 27-gauge, and 30-gauge needles. From the results, the gap width decreased with the decreasing of line distances. The gap width as a function of the line distances for different size of needles were plotted and shown in FIGS. 11a-11d, which FIGS. 11a and 11c are graphs of calculated variations of the mean gap width of DIW printed lines in mm with the increasing of the line distances in mm based on different size of needles, wherein FIG. 11a is related to 14-gauge, 15-gauge, 18-gauge, and 20-gauge needles, and FIG. 11c is related to 21-gauge, 22-gauge, 27-gauge, and 30-gauge needles, and FIGS. 11b and 11d are graphs of calculated variations of the overlap in % with the increasing of the line distances in mm based on different size of needles, FIG. 11b is related to 14-gauge, 15-gauge, 18-gauge, and 20-gauge needles, and FIG. 11d is related to 21-gauge, 22-gauge, 27-gauge, and 30-gauge needles. The overlap of the lines printed by using a 14-gauge needle was non-zero started at the point where the line distances were set to 1.2 mm, which means printing electrodes by using a 14-gauge needle should set the line distance equal to or lower than 1.2 mm to print electrodes without losing electrically conductive continuity. Therefore, 1.2 mm is the threshold value determined through this experiment results. The results showed that different size of needles have different threshold values. The threshold value can be regarded as a “property” of a given size of needle, which in some sense is a fixed value.

When the line distance in the designed electrodes' pattern is smaller than the threshold value, the overlap of printed adjacent lines starts to increase resulting in printed electrodes with electrically conductive continuity. For selected 14-gauge, 15-gauge, 18-gauge, and 20-gauge needles in this experiment, threshold values are 1.4 mm, 1.2 mm, 0.8 mm, and 0.6 mm, respectively. The results in FIG. 11b show the threshold values of 21-gauge, 22-gauge, and 27-gauge needles are 0.4 mm, 0.4 mm, and 0.2 mm, correspondingly. There was no overlap for lines printed using a 30-gauge needle even when the line distance decreased down to 0.2 mm. A smaller line distance should be selected to determine the threshold value for the 30-gauge needle, which was not studied in this experiment. Based on above mentioned results, the threshold value can also be defined as the point at which the overlap is greater than zero. The variations of overlap for different size of needles as the function of line distances are shown in FIGS. 11b and 11d. From FIGS. 11b and 11d, for a given size of needle, based on the overlap values, researchers can directly find out the maximum line distance that can be used in the designed electrodes' patterns without losing electrically conductive continuity. As explained above, increasing the line distance can reduce the printing time and the ink volume needed. Setting the line distance to a proper value can effectively print the designed electrodes' patterns. The data shown in FIGS. 11a-11d is thus a useful guideline for the electrodes' patterns design.

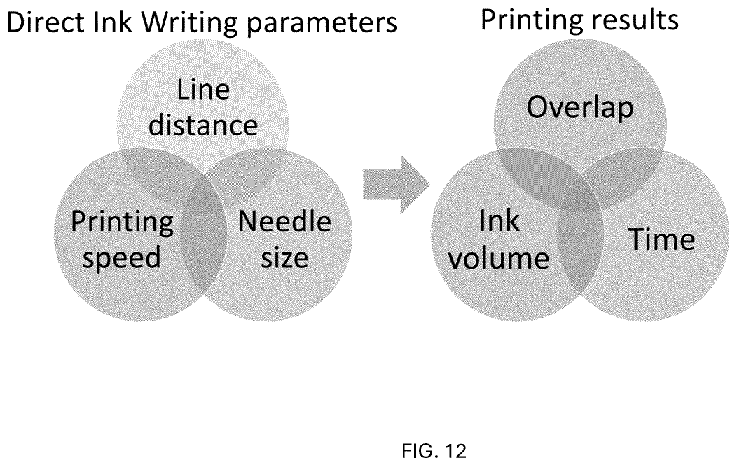

In summary, there are many parameters that can affect DIW printing of electrodes, however, the important parameters along with variations printing results are shown in FIG. 12, which is a schematic showing relationship between DIW parameters and printing results. By using DIW to print a fixed dimension of electrodes' pattern, the total time and total volume of the ink needed to complete the printing task are controlled by the line distance, needle size, and printing speed (i.e., the three important parameters of DIW writing). The optimization of the time and volume of ink needed to complete a printing task are significantly important for large scale manufacturing in industries.

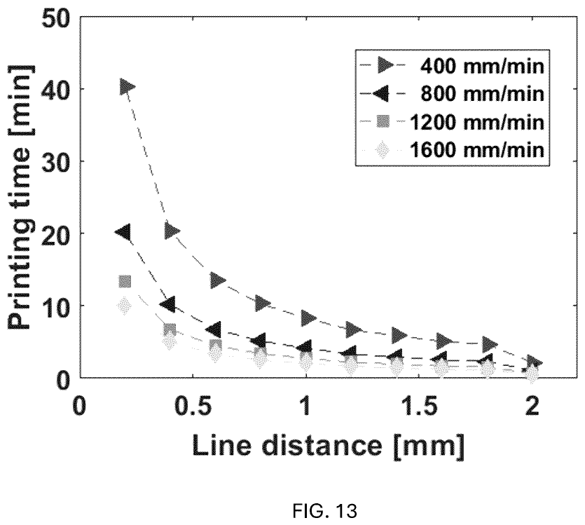

When printing a given electrode pattern (e.g., a 40 mm×40 mm square), the relationship between the printing time and the line distance for different printing speeds are shown in FIG. 13, which is a graph of printing time in minutes vs. line distance in mm for different printing speeds. The result shown are provided with other printing parameters kept constant. The printing time was calculated by using the total length of the printing path divided by the printing speed. Herein, the total length of the printing path was determined by the dimension of the electrode pattern and the line distance. In this experiment, a square shape electrode pattern with dimension of 40 mm×40 mm was used. The calculated total length of the printing path corresponding to different line distances are listed in Table 5. For a given electrode pattern, the total length of the printing path increased with the decreasing of the line distance. At a constant printing speed, the increasing of total printing path led to the increasing of printing time. Therefore, as the result shown in FIG. 13, the printing time and the line distance have a negative correlation and increasing the printing speed can definitely decrease the printing time.

TABLE 5
The calculated total length of the printing path under different line
distances based on a square shape electrode pattern (40 mm × 40 mm)

| | | | | | | | | | | |
|---|---|---|---|---|---|---|---|---|---|---|
| Line distance [mm] | 0.2 | 0.4 | 0.6 | 0.8 | 1.0 | 1.2 | 1.4 | 1.6 | 1.8 | 2.0 |
| Total length of | 0.8 | 1.88 | 2.04 | 2.36 | 2.68 | 3.32 | 4.12 | 5.40 | 8.12 | 16.12 |
| printing path [m] | | | | | | | | | | |

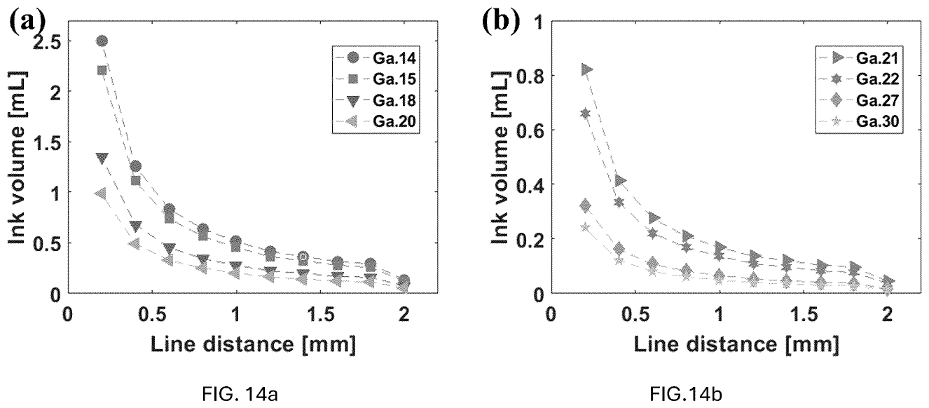

To further analyze the DIW printing of electrodes, the same electrode pattern (40 mm×40 mm) was still considered to be printed to study the relationship between the volume of ink needed and the line distance. The volume of ink needed to print a unit length of line during DIW is calculated by using the mean line width multiply the layer height, which is defined by the distance between the needle tip and the printing bed surface. Based on the above-mentioned calculation method, printing a unit length of line by using different size of needle, the volume of ink needed is different. The calculation results about the relationship between the volume of ink and the line distance by using different size of needles are shown in FIGS. 14a and 14b, which are graphs of ink volume in mL vs. line distance in mm (see definition provided in FIG. 1c) for 14 Gauge, 15 Gauge, 18 Gauge, and 20 Gauge (FIG. 14a), and for 21 Gauge, 22 Gauge, 27 Gauge, and 30 Gauge, needles sizes, respectively. The volume of ink increased with the decreasing of line distance. Printing the proposed electrode pattern by selecting a fixed line distance (e.g., 1.0 mm), the larger the size of the needle used the larger the volume of ink needed.

From the result shown in FIGS. 14a and 14b, to print the proposed electrode′ pattern with 0.2 mm as the line distance, the volume of ink needed by using a 14-gauge needle is about 2.5 mL. By comparison, the volume of ink needed by using a 30-gauge needle is much lower, which only needs to be about 0.24 mL. However, based on the relationship between the overlap and the line distance shown in FIGS. 11a-11d, the overlap of a 30-gauge needle is still zero when the line distance is set to 0.2 mm, which indicates the printed electrode loses its electrically conductive continuity. A smaller line distance should be set to succeed in printing the electrode using a 30-gauge needle. In that case, more volume of ink is needed and longer printing time is needed accordingly. In a short summary, the above findings prove the printing results are determined by multiplying of printing parameters and these parameters interact together to influence the final DIW printing results, which should be considered thoroughly to optimize the printing process to obtain a better printing result.

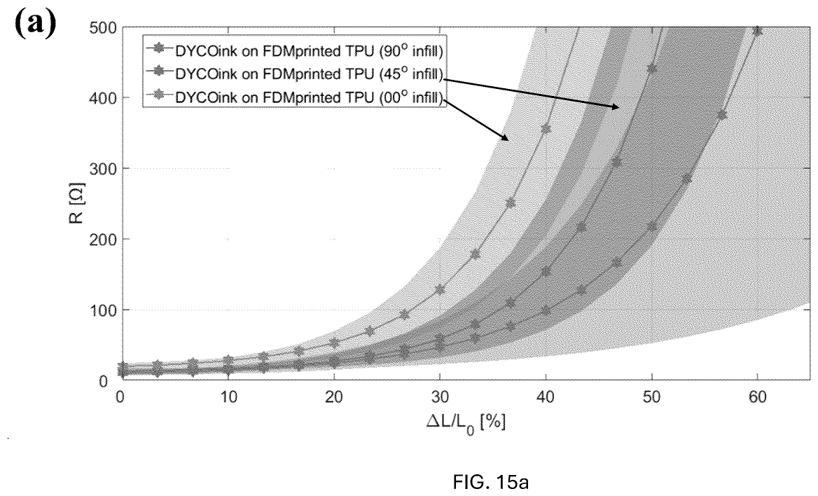

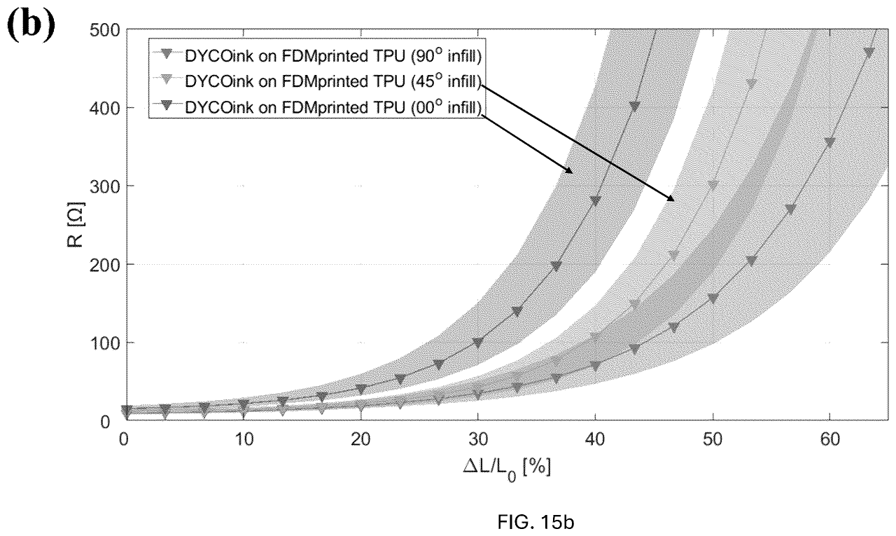

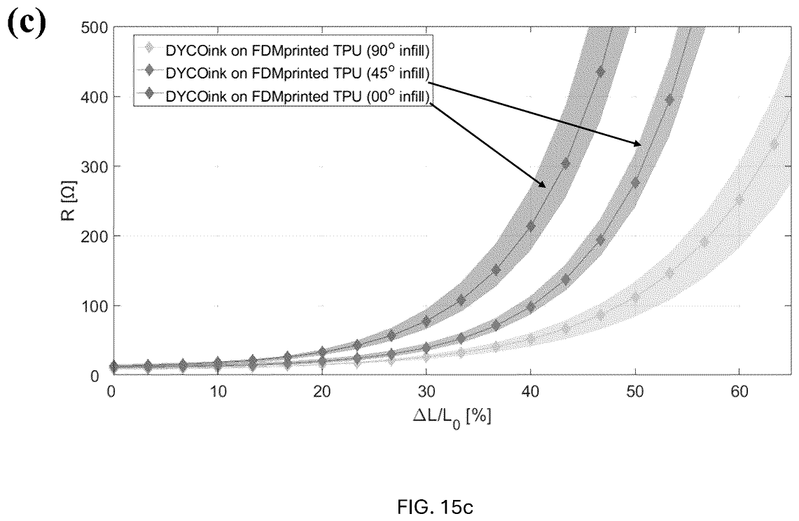

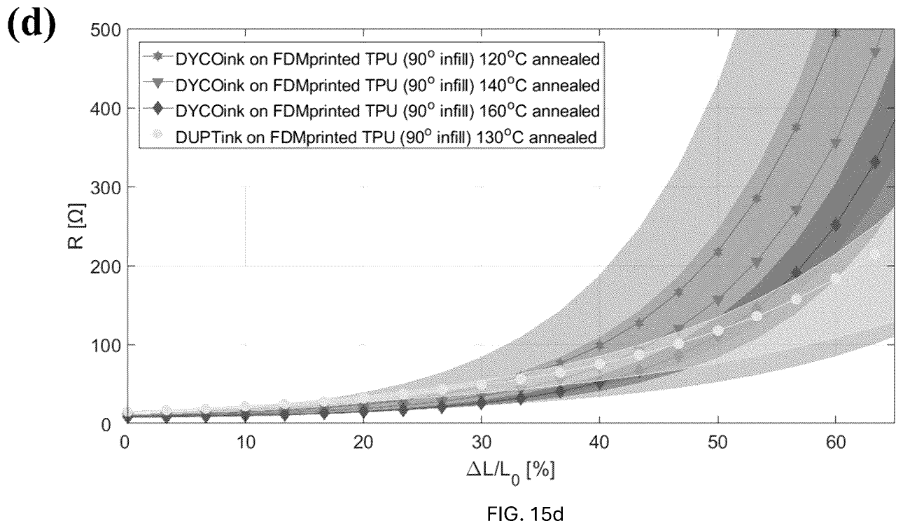

The measurement results of the variations of conductivity of DIW printed stretchable electrodes during stretching were plotted and shown in FIGS. 15a-15d, which are graphs of resistance in Q vs. deformation of the length (AL/L0) in % of the printed ink, wherein Dycotec silver electrodes printed on 3D printed TPU with different infill directions annealed at 120° C. are shown in FIG. 15a, 140° C. shown in FIG. 15b, 160° C. shown in FIG. 15c, and comparison of the performance between Dycotec silver electrodes and DuPont silver electrodes printed on 3D printed TPU with the same infill direction are shown in FIG. 15d. In these figures, the solid lines stand for the mean values of sample resistance in the same group. The lower boundary of each group stands for the minimum and the upper boundary stands for the maximum in the corresponding group. Samples in the same group were printed by using the same printing parameters on the same substrate (i.e., printed by the same infill direction) and subjected to the same annealing treatment (i.e., temperature and time). In general, the resistance of the printed stretchable electrodes can stay stable at a value around the initial resistance in the beginning of the stretching. When the deformation of the length (ΔL/L0) is smaller than 30% of the initial length, the resistances can keep lower than 100Ω for all groups. From the results of Dycotec ink annealed at 120° C. (shown in FIG. 1.18 (a)), the electrical conductivity of electrodes printed on 3D printed TPU substrates with different infill directions (i.e., 0°, 45° and) 90° have different performance characteristics. During the experiment, there were six samples in each group and samples in the same group were printed on 3D printed stretchable substrates and annealed at the same temperature for 10 minutes. Even electrodes printed on substrate with the same infill direction and subjected to the same annealing treatment, the resistances measured at the same stretching ratio (ΔL/L0) still have large variations, which is later quantified by standard deviation. For instance, before the stretching, the mean value of the resistance from the group printed on a 90° infill substrate annealed at 120° C. was 9.99Ω. When the stretching ratio was 30%, the resistance of one sample in this group was measured at 22.57Ω. And the resistance of the same sample was 84.91Ω even when the sample was stretched to 60%. By comparison, the resistance of another sample from the same group reached a value of about 84.05Ω measured at stretching ratio of 30% and then the resistance exponentially increased to reach 997.61Ω when the sample was stretched 50%.

The standard deviations can reflect the variations of the measured resistances from six samples in each group at the same stretching ratios. With the increasing of the stretching ratios, the standard deviations increased exponentially. Since the goal is to develop soft transducers for soft grippers and soft robotic applications, the research interests are focused on the electrodes' performance measured with the stretching ratio in the range from 0% to 30%. At the stretching ratio of 30%, the standard deviations of resistances measured from samples printed on 0°, 45° and 90° infill substrates annealed at 120° C. are 43.80, 22.32 and 22.18, respectively. These critical values including mean, maximum, minimum, standard deviation at corresponding stretching ratios for groups annealed at 120° C. are listed in Table 6, Table 7, and Table 8, which correspond to samples printed on 3D printed substrate with different infill directions (i.e., 0°, 45° and) 90°, respectively. With the increasing of annealing temperatures (as shown in FIG. 15b, Table 9, Table 10, and Table 11), the standard deviations from each group decreased. For the resistances measured from samples annealed at 140° C., the standard deviations are 33.14, 10.41, and 9.72 corresponding to samples printed on 0°, 45° and 90° infill substrates, respectively. When the annealing temperature reached 160° C. (see the data listed in Tables 12, 13, and 14), we are still interested in the data measured at stretching ratio of 30% and find that the standard deviations are 9.86, 4.30, and 2.33 corresponding to samples printed on 0°, 45° and 90° infill substrates, respectively. The standard deviations decreased with the increasing of annealing temperatures, which means the electrodes' performances among different samples printed on the same substrates and subjected to the same annealing treatment become stable with the increasing of annealing temperatures.

Besides the standard deviations, the change of the electrodes' resistances (4R) during stretching is also very important. The relationship can directly reflect the electrodes' performances which is strongly related to the applications. The change of resistance was calculated by using the resistance measured at a specific stretching ratio subtracting the initial resistance. In general, the change of resistance enlarged with the increasing of the stretching ratio. Comparing the data measured from samples at the same temperature, the stability of the resistance of samples printed on different infill substrates are different. The resistance of samples printed on 90° infill substrate are relatively stable compared with the data measured from samples printed on other two infill directions, which means the directions of 3D printed corn row structure on substrates can significantly influence the electrodes' performances especially during stretching.

It should be noted that for samples printed on the same infill substrates, increasing the annealing temperature can improve the stability of the resistance during the stretching. For instance, the percentage change ratio of resistance calculated from samples printed on 90° infill substrate annealed at 120° C. is 364.49% at 30% stretching ratio. With the increasing of the annealing temperature, the ratios calculated from samples annealed at 140° C. and 160° C. are 273.32% and 218.47%, respectively. The same trend was also shown on samples printed on the other two infill directions. In a short summary, the stretchable electrodes printed on the 3D printed 90° infill substrate annealed at 160° C. have the best performance. Herein, better performance means the changing rate of mean resistance with the increasing of the stretching ratio is smaller than that of other groups.

According to the present disclosure, the performance of DuPont ink is studied, and the result is shown in FIG. 15d. The data measured from the electrodes printed by using the Dycotec ink on 90° infill substrates annealed at three different temperatures (i.e., 120° C., 140° C., and 160° C.) were also plotted in the same figure for comparison. The DuPont ink was printed only on 90° infill substrates annealed at 130° C. for 15 minutes. The parameters for the annealing treatment were determined based on the manufacturer's datasheet. The critical values related to the performance of DuPont ink are listed in Table 15. The performance of the DuPont ink printed electrodes is better than that of Dycotec ink printed electrodes, because with the increasing of the stretching ratios from 0 to 30%, the corresponding ratios (ΔR/R0) increased from 0 to 112.42% which is only one half the ratio (i.e., 218.47%) calculated from samples printed by Dycotec ink which shows the best performance among all Dycotec ink printed samples

TABLE 6
Performance of Dycotec electrodes on 0° infill substrate annealed at 120° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 9.99 | 6.70 | 12.10 | 1.96 | 0.00 | 0.00 |
| 10 | 14.27 | 9.03 | 20.30 | 3.84 | 4.27 | 42.74 |
| 20 | 24.02 | 14.48 | 39.43 | 9.07 | 14.03 | 140.37 |
| 30 | 46.42 | 22.57 | 84.05 | 22.18 | 36.43 | 364.49 |
| 40 | 98.04 | 33.44 | 188.16 | 53.93 | 88.05 | 881.04 |
| 50 | 217.39 | 52.27 | 431.03 | 129.86 | 207.39 | 2075.19 |
| 60 | 493.91 | 84.91 | 997.61 | 310.15 | 483.92 | 4842.09 |

TABLE 7
Performance of Dycotec electrodes on 45° infill substrate annealed at 120° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 12.95 | 7.33 | 16.33 | 3.05 | 0.00 | 0.00 |
| 10 | 16.36 | 11.18 | 19.39 | 3.20 | 3.41 | 26.34 |
| 20 | 26.69 | 18.82 | 37.04 | 7.01 | 13.75 | 106.20 |
| 30 | 58.04 | 31.80 | 91.11 | 22.32 | 45.09 | 348.30 |
| 40 | 153.06 | 71.15 | 255.02 | 70.01 | 140.11 | 1082.32 |
| 50 | 441.14 | 190.43 | 751.96 | 214.99 | 428.20 | 3307.69 |
| 60 | 1314.56 | 552.09 | 2258.57 | 654.63 | 1301.62 | 10054.53 |

TABLE 8
Performance of Dycotec electrodes on 90° infill substrate annealed at 120° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 19.46 | 12.73 | 24.33 | 3.98 | 0.00 | 0.00 |
| 10 | 27.65 | 17.39 | 32.40 | 5.71 | 8.18 | 42.05 |
| 20 | 52.46 | 31.53 | 69.29 | 14.52 | 33.00 | 169.55 |
| 30 | 127.69 | 74.39 | 186.86 | 43.80 | 108.23 | 556.09 |
| 40 | 355.77 | 204.32 | 543.27 | 133.55 | 336.31 | 1728.00 |
| 50 | 1047.26 | 598.27 | 1623.86 | 405.94 | 1027.80 | 5280.97 |
| 60 | 3143.70 | 1792.62 | 4899.95 | 1231.87 | 3124.24 | 16052.81 |

TABLE 9
Performance of Dycotec electrodes on 0° infill substrate annealed at 140° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 9.28 | 7.75 | 10.40 | 1.13 | 0.00 | 0.00 |
| 10 | 12.17 | 10.15 | 15.00 | 1.77 | 2.89 | 31.15 |
| 20 | 18.91 | 15.52 | 25.73 | 4.03 | 9.63 | 103.81 |
| 30 | 34.64 | 25.13 | 50.78 | 9.72 | 25.36 | 273.32 |
| 40 | 71.33 | 46.71 | 109.20 | 23.16 | 62.05 | 668.77 |
| 50 | 156.93 | 97.05 | 245.48 | 54.60 | 147.65 | 1591.28 |
| 60 | 356.62 | 214.49 | 563.42 | 127.96 | 347.34 | 3743.36 |

TABLE 10
Performance of Dycotec electrodes on 45° infill substrate annealed at 140° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 12.40 | 9.26 | 14.03 | 1.81 | 0.00 | 0.00 |
| 10 | 14.70 | 10.95 | 17.27 | 2.34 | 2.30 | 18.57 |
| 20 | 21.68 | 16.06 | 27.09 | 4.22 | 9.28 | 74.85 |
| 30 | 42.84 | 30.80 | 56.88 | 10.41 | 30.44 | 245.50 |
| 40 | 107.00 | 70.15 | 147.18 | 29.50 | 94.60 | 762.88 |
| 50 | 301.51 | 189.43 | 420.97 | 87.53 | 289.11 | 2331.44 |
| 60 | 891.22 | 551.09 | 1251.01 | 263.51 | 878.82 | 7086.98 |

TABLE 11
Performance of Dycotec electrodes on 90° infill substrate annealed at 140° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 15.13 | 10.73 | 19.33 | 2.77 | 0.00 | 0.00 |
| 10 | 21.62 | 17.42 | 29.27 | 4.46 | 6.49 | 42.91 |
| 20 | 41.30 | 31.69 | 59.43 | 11.28 | 26.17 | 172.99 |
| 30 | 100.97 | 70.81 | 150.84 | 33.14 | 85.84 | 567.38 |
| 40 | 281.86 | 189.43 | 427.99 | 99.88 | 266.73 | 1763.08 |
| 50 | 830.30 | 549.04 | 1268.25 | 302.39 | 815.17 | 5388.18 |
| 60 | 2493.05 | 1639.31 | 3815.74 | 916.41 | 2477.92 | 16378.70 |

TABLE 12
Performance of Dycotec electrodes on 0° infill substrate annealed at 160° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 8.13 | 7.40 | 10.02 | 0.99 | 0.00 | 0.00 |
| 10 | 10.15 | 9.33 | 11.45 | 0.75 | 2.02 | 24.90 |
| 20 | 14.87 | 13.85 | 16.03 | 0.70 | 6.75 | 82.98 |
| 30 | 25.89 | 22.59 | 29.46 | 2.33 | 17.76 | 218.47 |
| 40 | 51.58 | 40.79 | 60.81 | 6.69 | 43.45 | 534.55 |
| 50 | 111.52 | 83.23 | 133.94 | 16.95 | 103.39 | 1271.92 |
| 60 | 251.35 | 182.25 | 304.53 | 40.94 | 243.22 | 2992.10 |

TABLE 13
Performance of Dycotec electrodes on 45° infill substrate annealed at 160° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 11.14 | 9.36 | 13.63 | 1.55 | 0.00 | 0.00 |
| 10 | 13.25 | 11.25 | 16.06 | 1.67 | 2.11 | 18.94 |
| 20 | 19.64 | 16.98 | 23.42 | 2.18 | 8.50 | 76.34 |
| 30 | 39.03 | 34.34 | 45.73 | 4.30 | 27.89 | 250.40 |
| 40 | 97.81 | 86.96 | 113.39 | 11.46 | 86.67 | 778.08 |
| 50 | 276.01 | 240.66 | 318.51 | 33.57 | 264.87 | 2377.91 |
| 60 | 816.27 | 706.41 | 940.38 | 100.76 | 805.14 | 7228.23 |

TABLE 14
Performance of Dycotec electrodes on 90° infill substrate annealed at 160° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 13.00 | 9.73 | 15.63 | 2.19 | 0.00 | 0.00 |
| 10 | 17.86 | 14.39 | 20.09 | 2.12 | 4.87 | 37.44 |
| 20 | 32.61 | 28.53 | 36.88 | 3.30 | 19.62 | 150.96 |
| 30 | 77.34 | 66.03 | 94.68 | 9.86 | 64.34 | 495.13 |
| 40 | 212.94 | 178.98 | 269.91 | 31.18 | 199.94 | 1538.56 |
| 50 | 624.05 | 521.42 | 801.19 | 96.28 | 611.06 | 4702.02 |
| 60 | 1870.45 | 1559.65 | 2411.89 | 293.75 | 1857.45 | 14292.95 |

TABLE 15
Performance of DuPont electrodes on 90° infill substrate annealed at 150° C.

| ΔL/L₀ [%] | Mean [Ω] | Minimum [Ω] | Maximum [Ω] | std | ΔR [Ω] | ΔR/R₀ [%] |
|---|---|---|---|---|---|---|
| 0 | 15.08 | 13.79 | 15.93 | 0.88 | 0.00 | 0.00 |
| 10 | 21.63 | 19.79 | 22.93 | 1.29 | 6.55 | 43.46 |
| 20 | 32.03 | 27.49 | 34.80 | 2.59 | 16.95 | 112.42 |
| 30 | 48.56 | 38.48 | 53.94 | 5.42 | 33.48 | 222.01 |
| 40 | 74.86 | 54.18 | 84.78 | 10.83 | 59.78 | 396.44 |
| 50 | 116.78 | 76.61 | 134.51 | 20.71 | 101.70 | 674.41 |
| 60 | 183.66 | 108.65 | 214.66 | 38.28 | 168.58 | 1117.93 |

Having discussed PVdF microfiber structure and DIW printed electrodes, the combination of the two is now discussed. The performance of DuPont ink is studied, and the result is shown in FIG. 15d. The data measured from the electrodes printed by using the Dycotec ink on 90° infill substrates annealed at three different temperatures (i.e., 120° C., 140° C., and 160° C.) were also plotted in the same figure for comparison. The DuPont ink was printed only on 90° infill substrates annealed at 130° C. for 15 minutes. The parameters for the annealing treatment were determined based on the manufacturer's datasheet. The critical values related to the performance of DuPont ink are listed in Table 15. The performance of the DuPont ink printed electrodes is better than that of Dycotec ink printed electrodes, because with the increasing of the stretching ratios from 0 to 30%, the corresponding ratios (ΔR/R0) increased from 0 to 112.42% which is only one half the ratio (i.e., 218.47%) calculated from samples printed by Dycotec ink which shows the best performance among all Dycotec ink printed samples.

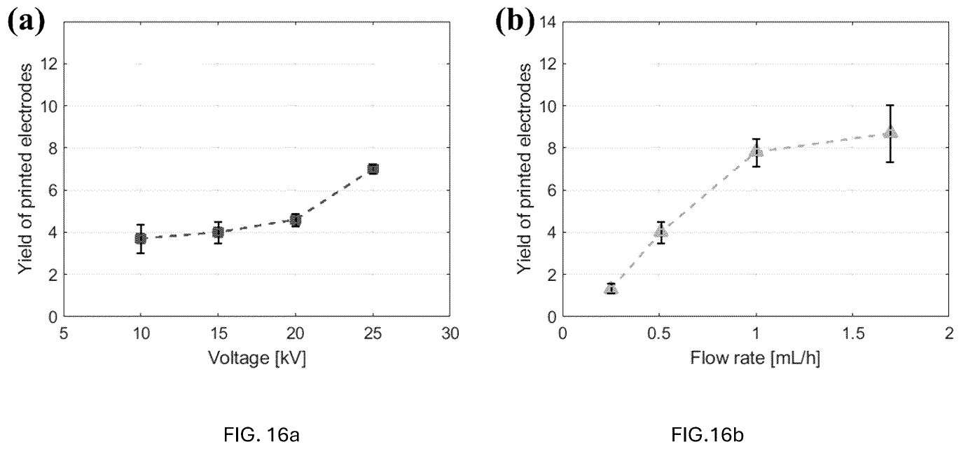

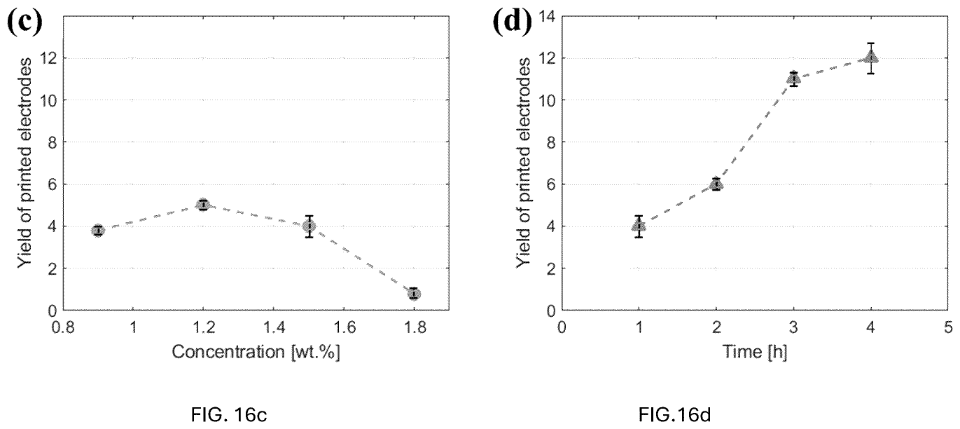

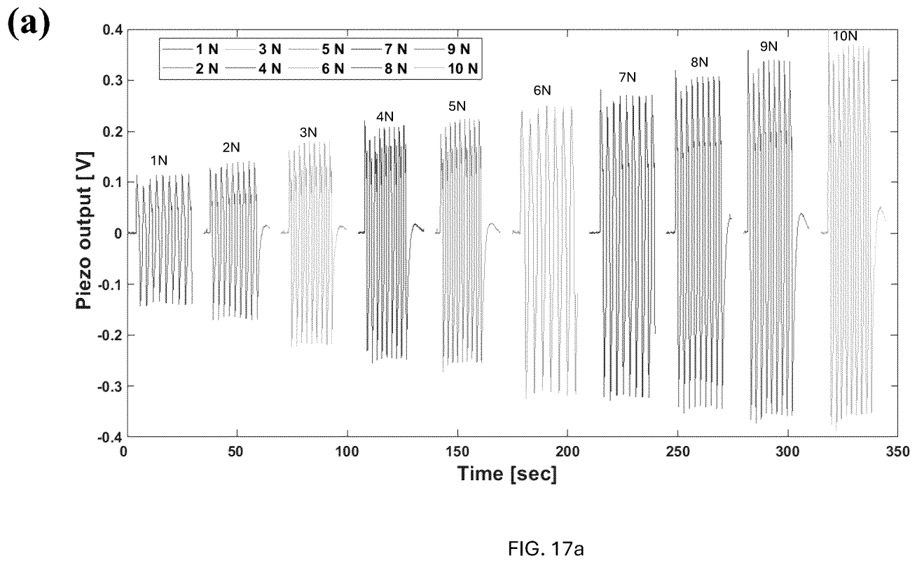

Same to the experiment plans carried out previously to study the influence of electrospinning parameters on the surface morphology and β-phase content, four typical electrospinning parameters were selected and studied. The experiment was still performed by adjusting only one parameter and keeping other parameters constant. The experiment results are plotted and shown in FIGS. 16a-16d, which are graphs of yield of the printed electrodes vs. voltage in KV (FIG. 16a), flow rate in mL/h (FIG. 16b), concentration in Wt. % (FIG. 16c), and time in hours (FIG. 16d). The influence of electrospinning voltage, flow rate, and time on the yield of printed silver electrodes shows monotonic variation trends. With the increase of the electrospinning voltage, the flow rate, and the elongation of the time, the yield increases accordingly. When studying the influence of solution concentration, the maximum yield appears at 12 wt. % concentration. For a lower polymer concentration, a stable polymer solution jet cannot form, and electrospinning microfibers cannot be produced effectively. When a much higher polymer concentration (i.e., 18 wt. %), the viscous polymer solution cannot be electrically stretched to form microfibers because of the entanglement of polymer chains, which explains the results shown in FIG. 16c.

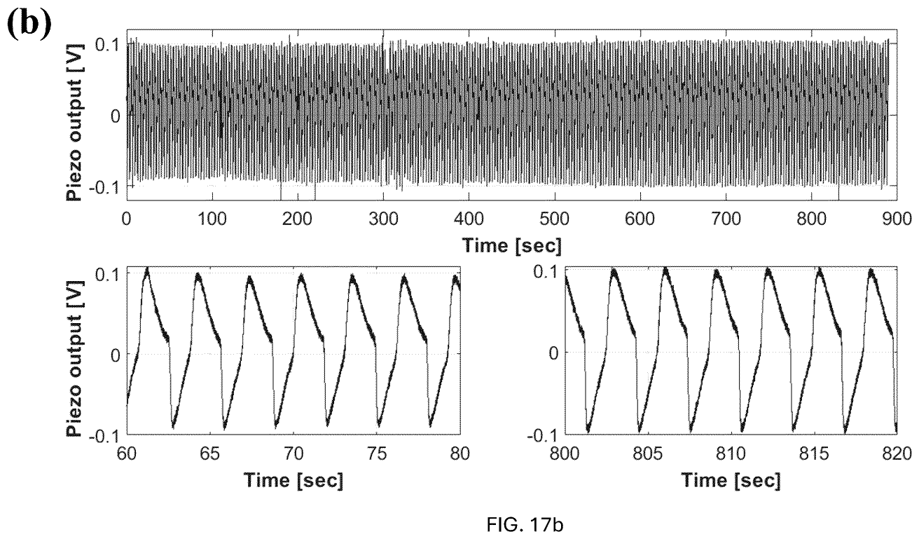

Next performance of the transducer is considered. To test the transducer's performance, the transducer is operated as a piezoelectric device. The performance of the resulting piezoelectric electrospinning PVdF microfiber-based pressure sensor is determined by measuring the piezoelectric output while applying a series of known mechanical input (i.e., forces). FIGS. 17a and 17b, which are graphs of piezoelectric output in V vs. time in seconds is provided by applying a series of step-increased known forces from 1 N to 10 N with 1 N as the increment (FIG. 17a) and applying cyclic forces with magnitude 1 N, 0.5 Hz for about 890 seconds (about 15 minutes), as provided in FIG. 17b which also provides zoomed in portions between 60 to 80 seconds as well as 800 to 820 seconds. The sensor was found to generate a positive pulse-shape voltage as the piezoelectric output in response to a compression force. When the sensor was decompressed, a negative pulse-shape voltage was produced by the sensor. The characteristics of these output signals is similar to that of generated by 3D printed PVdF materials-based pressure sensors.

It should be noted that the magnitude of the compressive stress and strain has a positive linear correlation with the magnitude of electric outputs. Increasing the compressive force from 0.5 to 15.0 N led to an increase in the piezoelectric output (see FIG. 17a), and the electric outputs at low forces followed different trends to those at higher ones. At a force range of 0.5-4.0 N, the voltage and current showed rapid increase with increasing the force, whereas slight increase in electric outputs resulted when the force increased from 4.0 to 15.0 N. This pattern indicates that the fibers experienced elastic deformations at a low compression load, and a larger compression load causes the rearrangement of the compressed fibers. It was difficult to precisely adjust the strain during measurement due to the thin and flexible features of the PVdF fiber mesh. Therefore, in the next step of research, the compression forces applied were lower than 10.0 N to test all PVdF fiber mesh.

The excellent mechanical-to-electrical energy conversion properties of the electrospinning PVDF nano mesh can be explained by two reasons: (1) the dense fibrous structure facilitates charge transfer across the network and hence decreasing the internal resistance, and (2) the fiber-fiber interconnection implemented through the printed silver electrode assists in charge transfer because it eliminates the boundary. These allow the mechanical-to-electrical energy conversion in sensors with printed silver electrodes more efficient than that of sensors with applied conductive tapes as electrodes. By applying a series of known forces from 1 N to 10 N at a constant frequency of 0.5 Hz, the measured signals show that the amplitude of the generated piezoelectric output voltage (i.e., the peak value) have a positive linear correlation with the magnitude of the applied mechanical forces, which proves the validity of the proposed electrospinning PVdF-based device can work as a piezoelectric force sensor with sensitivity of 27.8 mV/N.

The durability and the stability of the sensor's performance were tested. The cyclic mechanical input (i.e., forces) with the magnitude of 1.2 N at a frequency of 0.5 Hz was applied continuously for about 15 minutes on the tested sensor. During the test, the sensor experienced loading-and-unloading cycles repeatedly and generated piezoelectric output signals shown in FIG. 1.20(b). The piezoelectric output measured within two specific time periods (i.e., one from 60 sec to 80 sec, and another from 800 sec to 820 sec) are replotted in a better view to show the stability of the generated piezoelectric output signals.

Based on the material presented herein, it can be concluded that the performance of the electrospinning PVdF microfiber-based piezoelectric pressure sensor largely depends on the piezoelectric characteristics of PVdF microfibers. The electrospinning parameters play an important role in controlling the surface morphology including the size distribution of microfibers and microbeads, the β-phase content, and, even later proved, to influence of the yield of printed electrodes. The β-phase content is mainly responsible for the piezoelectric output characteristics. The influence of voltage potential, solution flow rate, and polymer solution concentration as the major parameters on the β-phase content were studied systematically. Although these three parameters were all studied individually by keeping other parameters constant, the results show the β-phase content does not show a monotonic variation trend by individually increasing the values of any of these three parameters. Based on the results, these electrospinning parameters can interact together to influence the produced PVdF microfibers. The voltage and flow rate belongs to the electrospinning process parameters, and the polymer solution concentration belongs to the polymer solution characteristics. Besides, ambient parameters can also have an important influence on the electrospinning PVdF microfibers, which are ignored and assumed to be constant in this study. To better control the characteristics of the electrospinning PVdF microfibers, more parameters from the above-mentioned categories should be considered and the combination of them should be optimized.

To optimize the PVdF-phase characteristics, the graphs provided in FIGS. 7a-7c can be used to generate functions based on each parameter (i.e., β(Voltage), β(Concentration), and β(Flow Rate)) to optimize the β-phase. Each of these three functions can be curve-fit into a mathematical function, after which a processor executing instructions housed on a non-transient memory can numerically determine the derivative of each of these functions in order to determine the global maximum for each. Thus, the maximum β-phase for each of the parameters can be found, assuming no one parameter has an effect on any other parameter insofar as the β-phase is concerned. The same process can be repeated for the yield based on FIGS. 16a-16d, to optimize yield. That is, functions can be generated based on each parameter (i.e., Y(Voltage), Y(Concentration), and Y(Flow Rate), where Y is yield). Each of these three functions can be curve-fit into a mathematical function, after which a processor executing instructions housed on a non-transient memory can numerically determine the derivative of each of these functions in order to determine the global maximum for each. Thus, the maximum yield for each of the parameters can be found, assuming no one parameter has an effect on any other parameter insofar as the yield is concerned. Still the same process can be applied to the DIW printing process based on FIGS. 10a-10b, 11a-11d, and 13 to obtain the most satisfactory solution.

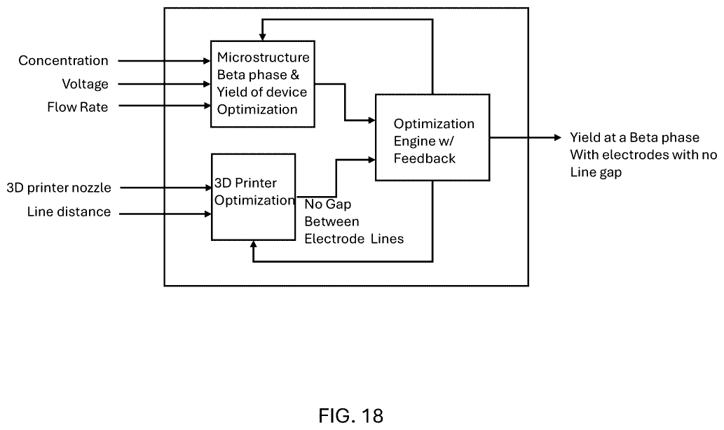

Towards this end, a block diagram is provided in FIG. 18, that shows the optimization processes for yield, β-phase, and electrode configuration to ensure a minimum proximity of lines to each other. As shown in FIG. 18, for yield and β-phase, three parameters are taken into account. These three parameters are 1) Concentration of the polymer solution, 2) Voltage applied during the electrospinning process, and 3) flow rate of the polymer solution out of the needle. An initial value within predetermined thresholds is initially used for each of these three parameters. Using the numerical derivative method or another optimization method, e.g., mean squared errors can be used to provide a feedback to the initial optimization block in order to optimize the yield and β-phase for the three enumerated parameters. A similar process (i.e., mean squared errors) can be undertaken to optimize the electrode printing process where the two main parameters are found to be nozzle size and line distance. The goal of this optimization is to strike a balance between printer nozzle and line distance such that 1) no gap is found between the printed lines and least amount of ink is used. Again a feedback signal is provided from the optimization engine to ensure the best tradeoff is met.

Those having ordinary skill in the art will recognize that numerous modifications can be made to the specific implementations described above. The implementations should not be limited to the particular limitations described. Other implementations may be possible.

1. A method of making a stretchable transducer, comprising:
placing a polymer solution having a concentration (C) in an injectable vessel having an electrically conductive ejection port;
applying a voltage (V) between the ejection port and an electrically conductive collection plate a predetermined distance away from the ejection port;
ejecting the polymer solution from the injectable vessel at a flow rate (FR), thereby generating a fibrous material having a considerable β-phase on the collection plate due to electrospinning;
removing the fibrous material from the collection plate;
depositing conductive electrodes on top and bottom surfaces of the removed fibrous material, thereby generating a transducer; and
simultaneously optimizing formation of β-phase of the fibrous material and yield of the transducer based on unwanted electrical current leakage between deposited electrodes on the top and bottom surfaces based on C, V, and FR.

2. The method of claim 1, wherein the formed transducer is a piezoelectric sensing device, adapted to generate an electrical signal across the electrodes in response to changes in the environment.

3. The method of claim 1, wherein the formed transducer is a piezoelectric actuating device, adapted to generate changes in the environment in response to an electrical signal placed across the electrodes.

4. The method of claim 1, wherein the polymer solution includes Polyvinylidene fluoride or polyvinylidene difluoride (PVdF).

5. The method of claim 1, wherein the electrodes are deposited using a direct ink writing (DIW) method.

6. The method of claim 1, wherein the electrodes are deposited using silver ink.

7. The method of claim 1, wherein the fibrous material includes strands and beads.

8. The method of claim 4, wherein the applied voltage is between about 10 to about 25 KV.

9. The method of claim 8, wherein the β-phase is between about 58% to about 72%.

10. The method of claim 4, wherein the concentration of the polymer solution is between about 9% to about 18%.

11. The method of claim 10, wherein the β-phase is between about 64% to about 72%.

12. The method of claim 4, wherein the flow rate is between about 0.25 mL/h to about 1.75 mL/h.

13. The method of claim 12, wherein the β-phase is between about 62% to about 72%.

14. The method of claim 5, further comprising electrode deposition by optimizing line distance between lines of printed electrode and nozzle size of the DIW.

15. The method of claim 14, wherein a threshold for acceptable DIW printed electrodes is with at least abutting lines.

16. The method of claim 14, wherein Gauge of nozzle size is between gauge 14 and gauge 30.
